(19) United States
(12) Patent Application Publication
(10) Pub. No.: US 2025/0008791 A1
(43) Pub. Date: Jan. 2, 2025

(54) Display Substrate and Preparation Method Therefor, and Display Device

(71) Applicants: Chengdu BOE Optoelectronics Technology Co., Ltd., Chengdu, Sichuan (CN); BOE Technology Group Co., Ltd., Beijing (CN)

(72) Inventors: Tinghua SHANG, Beijing (CN); Yi ZHANG, Beijing (CN); Yang ZHOU, Beijing (CN); Huijuan YANG, Beijing (CN); Hongwei MA, Beijing (CN)

(21) Appl. No.: 18/292,349

(22) PCT Filed: Aug. 18, 2022
(86) PCT No.: PCT/CN2022/113389

§ 371 Date: Jan. 26, 2024

(51) Int. Cl. H10K 59/131; H01L 27/12; H10K 59/12; H10K 59/121; H10K 71/60

(52) U.S. Cl. CPC H10K 59/131; H10K 59/1201; H10K 59/1213; H10K 59/1216; H10K 71/60; H01L 27/124

(57) ABSTRACT

A display substrate and a preparation method therefor, and a display device are provided. The display substrate includes a substrate, a plurality of initial signal lines and K rows and L columns of sub-pixels are provided on the substrate, K and L are each a positive integer greater than 1; a plurality of pixel column spaces are included between L pixel columns, the pixel column space is located between two adjacent pixel columns; at least one of the pixel column spaces is provided with initial signal connection lines, at least one of the initial signal connection lines is electrically connected to the plurality of initial signal lines through a via hole, on a plane parallel to the display substrate, the plurality of initial signal lines extend in a first direction and are arranged in a second direction.

### CROSS-REFERENCE TO RELATED APPLICATION

The present application is a U.S. National Phase Entry of International Application No. PCT/CN2022/113389 having an international filing date of Aug. 18, 2022. The above-identified application is hereby incorporated by reference.

### TECHNICAL FIELD

The present disclosure relates to, but is not limited to, the field of display technology, and particularly to a display substrate and a preparation method therefor, and a display device.

### BACKGROUND

An Organic Light Emitting Diode (OLED) and a Quantum dot Light Emitting Diode (QLED) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In a first aspect, an embodiment of the present disclosure provides a display substrate, including a substrate, wherein a plurality of initial signal lines and K rows and L columns of sub-pixels are provided on the substrate, K and L are each a positive integer greater than 1; a plurality of pixel column spaces are arranged between L pixel columns, a pixel column space is located between two adjacent pixel columns; at least one of the pixel column spaces is provided with initial signal connection lines, at least one of the initial signal connection lines is electrically connected to the plurality of initial signal lines through a via hole, on a plane parallel to the display substrate, the plurality of initial signal lines are extended in a first direction and are arranged in a second direction, the initial signal connection lines extend in the second direction, and the first direction intersects the second direction.

In an exemplary implementation, the plurality of pixel column spaces include a plurality of first pixel column spaces and a plurality of second pixel column spaces, orthographic projections of the first pixel column spaces and the second pixel column spaces on the substrate do not overlap.

The initial signal lines include a first initial signal line and a second initial signal line, the initial signal connection lines include a first initial signal connection line and a second initial signal connection line, the first initial signal connection line is disposed in the first pixel column space, the second initial signal connection line is disposed in the second pixel column space, the first initial signal connection line is electrically connected to the first initial signal line through a via hole, and the second initial signal connection line is electrically connected to the second initial signal line through a via hole.

In an exemplary implementation, L data signal lines corresponding to L pixel columns respectively are further provided on the substrate, on a plane parallel to the display substrate, the L data signal lines extend in the second direction and are arranged in the first direction, in the first direction, any one of the data signal lines is located on a side of a corresponding pixel column.

On a plane parallel to the display substrate, in the first direction, the pixel column space is located at a side of the data signal line away from the corresponding pixel column, the pixel column space is located between two adjacent data signal lines; or the pixel column space is located at a side of the pixel column away from the corresponding data signal line, and the pixel column space is located between two adjacent pixel columns.

In an exemplary implementation, in a plane perpendicular to the display substrate, the display substrate includes the substrate, and a first semiconductor layer, a first conductive layer, a second conductive layer, a second semiconductor layer, a third conductive layer, a fourth conductive layer and a fifth conductive layer which are sequentially stacked on the substrate.

The first semiconductor layer at least includes active layers of a plurality of low temperature polysilicon transistors; the first conductive layer at least includes control electrodes of the plurality of low temperature polysilicon transistors, and a first plate of a storage capacitor; the second conductive layer at least includes a second plate of the storage capacitor and the first initial signal lines; the second semiconductor layer at least includes active layers of a plurality of oxide transistors; the third conductive layer at least includes control electrodes of the plurality of oxide transistors; the fourth conductive layer at least includes first electrodes and second electrodes of the plurality of low temperature polysilicon transistors, first electrodes and second electrodes of the plurality of oxide transistors, and the second initial signal line; and the fifth conductive layer at least includes the first initial signal connection line and the second initial signal connection line.

In an exemplary implementation, the fourth conductive layer further includes a first initial signal connection electrode and a second initial signal connection electrode, the second initial signal connection electrode and the second initial signal line are an integrally molded structure;

The first initial signal connection electrode is electrically connected to the first initial signal line and the first initial signal connection line respectively through different via holes, and the second initial signal connection line is electrically connected to the second initial signal connection electrode through a via hole.

In an exemplary implementation, the plurality of low temperature polysilicon transistors includes a first transistor as a first initialization transistor, and a first electrode of the first transistor and the first initial signal connection electrode are an integrally molded structure.

In an exemplary implementation, L data signal lines corresponding to L pixel columns respectively are further provided on the substrate, on a plane parallel to the display substrate, the L data signal lines extend in the second direction and are arranged in the first direction, in the first direction, any one of the data signal lines is located on a side of a corresponding pixel column.

On a plane parallel to the display substrate, in the first direction, the pixel column space is located on a side of the data signal line away from a corresponding pixel column, the pixel column space is located between two adjacent data signal lines, the first pixel column space and the second pixel column space are alternately arranged in the first direction, two columns of sub-pixels are provided between two adjacent pixel column spaces, first electrodes of two first transistors located between two adjacent pixel column spaces are an integrally molded structure, the first initial signal connection electrode extends in the first direction, one end of the first initial signal connection electrode is provided with an electrode connection block, the other end of the first initial signal connection electrode is connected to the integrally molded first electrodes of the two first transistors, and there is an overlapping area between an orthographic projection of the electrode connection block on the substrate and an orthographic projection of the first pixel column space on the substrate.

In an exemplary implementation, a first power supply line is further provided on the fifth conductive layer, the first power supply line is electrically connected to the second plate through a via hole, the first power supply lines in a same pixel column are an integrally molded structure, and the first power supply lines corresponding to two columns of pixels located between two adjacent pixel column spaces are an integrally molded structure.

In an exemplary implementation, L data signal lines corresponding to L pixel columns respectively are further provided on the substrate, on a plane parallel to the display substrate, the L data signal lines extend in the second direction and are arranged in the first direction, in the first direction, any one of the data signal lines is located at a side of a corresponding pixel column.

On a plane parallel to the display substrate, in the first direction, the pixel column space is located at a side of the pixel column away from a corresponding data signal line, the pixel column space is located between two adjacent pixel columns, the first pixel column space and the second pixel column space are alternately arranged in the first direction, two columns of sub-pixels are provided between two adjacent pixel column spaces, the first initial signal connection electrode and first electrodes of two first transistors located on both sides of the first pixel column space are an integrally molded structure, and there is an overlapping area between an orthographic projection of the first initial signal connection electrode on the substrate and an orthographic projection of the first pixel column space on the substrate.

In an exemplary implementation, a first power supply line is further provided on the fifth conductive layer, the first power supply line is electrically connected to the second plate through a via hole, and the first power supply lines in a same pixel column are an integrally molded structure.

In an exemplary implementation, the first electrode of the first transistor is electrically connected to the active layer of the first transistor and the first initial signal line through different via holes, respectively, and the first initial signal connection electrode is electrically connected to the first initial signal connection line through a via hole.

In an exemplary implementation, at least one sub-pixel includes a pixel drive circuit electrically connected to the initial signal line, the pixel drive circuit at least includes a plurality of transistors, and the plurality of transistors at least include a first transistor as a first initialization transistor and a seventh transistor as a second initialization transistor. A first electrode of the first transistor is electrically connected to the first initial signal line, and a first electrode of the seventh transistor is electrically connected to the second initial signal line.

In an exemplary implementation, the pixel drive circuit further includes a storage capacitor electrically connected to a second electrode of the first transistor, on a plane parallel to the display substrate, in the second direction, the first transistor and the seventh transistor are located at both sides of the storage capacitor, and the first initial signal line and the second initial signal line are located at both sides of the storage capacitor.

In an exemplary implementation, the plurality of transistors further include a fourth transistor as a data writing transistor, a plurality of scan signal lines extending in the first direction are further provided on the substrate, the plurality of scan signal lines at least include a first scan signal line and a third scan signal line, the first scan signal line serves as a control electrode of the seventh transistor, and the third scan signal line serves as a control electrode of the fourth transistor; on a plane parallel to the substrate, in the second direction, orthographic projections of the first scan signal line and the third scan signal line on the substrate are located at both sides of an orthographic projection of the storage capacitor on the substrate.

In an exemplary implementation, the plurality of transistors further include a second transistor as a compensation transistor, a fifth transistor and a sixth transistor as light emitting transistors, the plurality of scan signal lines further include a second scan signal line, a fourth scan signal line and a light emitting control line, the second scan signal line serves as a control electrode of the first transistor, the fourth scan signal line serves as a control electrode of the second transistor, and the light emitting control line serves as a control electrode of the fifth transistor and the sixth transistor; in a same pixel row, in a plane where the display substrate is located, the second initial signal line, the first scan signal line, the light emitting control line, the storage capacitor, the fourth scan signal line, the third scan signal line, the second scan signal line and the first initial signal line are sequentially arranged in the second direction.

In an exemplary implementation, the plurality of transistors further includes a third transistor as a drive transistor, and there is an overlapping area between an orthographic projection of the third transistor on the substrate and an orthographic projection of the storage capacitor on the substrate.

In an exemplary implementation, the first transistor and second transistor are oxide transistors, and the third transistor to the seventh transistor are low temperature polysilicon transistors.

In a second aspect, an embodiment of the present disclosure further provides a display device, including the display substrate according to any one of the embodiments described above.

In a third aspect, an embodiment of the present disclosure further provides a preparation method for a display substrate, wherein the display substrate includes a substrate, a plurality of initial signal lines and K rows and L columns of sub-pixels are provided on the substrate, K and L are each a positive integer greater than 1; the plurality of initial signal lines extend in a first direction and are arranged in a second direction, the first direction intersects the second direction; a plurality of pixel column spaces are arranged between the L pixel columns, and a pixel column space is located between two adjacent pixel columns; the preparation method including:

Disposing initial signal connection lines in at least one of the pixel column spaces, and electrically connecting at least one of the initial signal connection lines to the plurality of initial signal lines through a via hole, the initial signal connection lines extending in the second direction on a plane parallel to the display substrate.

In an exemplary implementation, the plurality of pixel column spaces include a plurality of first pixel column spaces and a plurality of second pixel column spaces, orthographic projections of the first pixel column spaces and the second pixel column spaces on the substrate do not overlap; the initial signal lines include a first initial signal line and a second initial signal line, the initial signal connection lines include a first initial signal connection line and a second initial signal connection line, the first initial signal connection line is disposed in the first pixel column space, the second initial signal connection line is disposed in the second pixel column space, the first initial signal connection line is electrically connected to the first initial signal line through a via hole, and the second initial signal connection line is electrically connected to the second initial signal line through a via hole.

After the drawings and the detailed descriptions are read and understood, the other aspects may be comprehended.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and do not form limitations on the technical solutions of the present disclosure. Shapes and sizes of each component in the drawings do not reflect actual scales, and are only intended to schematically illustrate contents of the present disclosure.

FIG. 1 is a schematic diagram of a structure of a display device.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is a schematic diagram of an equivalent circuit of a pixel drive circuit.

FIG. 6 is a working timing diagram of a pixel drive circuit.

FIG. 7a is a schematic diagram of a structure of a substrate according to an exemplary embodiment of the present disclosure.

FIG. 7b is a schematic diagram of a structure of a substrate according to an exemplary embodiment of the present disclosure.

FIG. 8a is a schematic diagram of a structure of a substrate according to an exemplary embodiment of the present disclosure.

FIG. 8b is a schematic diagram of a structure of a substrate according to an exemplary embodiment of the present disclosure.

FIG. 9 is a schematic diagram after a pattern of a shielding layer is formed according to an exemplary embodiment of the present disclosure.

FIG. 10a and FIG. 10b are schematic diagrams after a pattern of a first semiconductor layer is formed according to an exemplary embodiment of the present disclosure.

FIG. 11a and FIG. 11b are schematic diagrams after a pattern of a first conductive layer is formed according to an exemplary embodiment of the present disclosure.

FIG. 12a and FIG. 12b are schematic diagrams after a pattern of a second conductive layer is formed according to an exemplary embodiment of the present disclosure.

FIG. 13a and FIG. 13b are schematic diagrams after a pattern of a second semiconductor layer is formed according to an exemplary embodiment of the present disclosure.

FIG. 14a and FIG. 14b are schematic diagrams after a pattern of a third conductive layer is formed according to an exemplary embodiment of the present disclosure.

FIG. 15 is a schematic diagram after a pattern of a sixth insulation layer is formed according to an exemplary embodiment of the present disclosure.

FIG. 16a and FIG. 16b are schematic diagrams after a pattern of a fourth conductive layer is formed according to an exemplary embodiment of the present disclosure.

FIG. 17 is a schematic diagram after a pattern of a first planarization layer is formed according to an exemplary embodiment of the present disclosure.

FIG. 18a and FIG. 18b are schematic diagrams after a pattern of a fifth conductive layer is formed according to an exemplary embodiment of the present disclosure.

FIG. 19 is a schematic diagram after a pattern of a shielding layer is formed according to an exemplary embodiment of the present disclosure.

FIG. 20a and FIG. 20b are schematic diagrams after a pattern of a first semiconductor layer is formed according to an exemplary embodiment of the present disclosure.

FIG. 21a and FIG. 21b are schematic diagrams after a pattern of a first conductive layer is formed according to an exemplary embodiment of the present disclosure.

FIG. 22a and FIG. 22b are schematic diagrams after a pattern of a second conductive layer is formed according to an exemplary embodiment of the present disclosure.

FIG. 23a and FIG. 23b are schematic diagrams after a pattern of a second semiconductor layer is formed according to an exemplary embodiment of the present disclosure.

FIG. 24a and FIG. 24b are schematic diagrams after a pattern of a third conductive layer is formed according to an exemplary embodiment of the present disclosure.

FIG. 25 is a schematic diagram after a pattern of a sixth insulation layer is formed according to an exemplary embodiment of the present disclosure.

FIG. 26a and FIG. 26b are schematic diagrams after a pattern of a fourth conductive layer is formed according to an exemplary embodiment of the present disclosure.

FIG. 27 is a schematic diagram after a pattern of a first planarization layer is formed according to an exemplary embodiment of the present disclosure.

FIG. 28a and FIG. 28b are schematic diagrams after a pattern of a fifth conductive layer is formed according to an exemplary embodiment of the present disclosure.

### DETAILED DESCRIPTION

Embodiments of the present disclosure will be described below in with reference to the drawings in detail. Implementations may be practiced in multiple different forms. Those of ordinary skill in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other in case of no conflicts. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a thickness and a pitch of each film layer, and a width and a pitch of each signal line may be adjusted according to an actual situation. The drawings described in the present disclosure are only schematic diagrams of structures, and one implementation of the present disclosure is not limited to shapes or numerical values or the like shown in the drawings.

Ordinal numerals “first”, “second”, “third”, etc., in the specification are set not to form limits in number but only to avoid the confusion of composition elements.

In the specification, for convenience, expressions “central”, “above”, “below”, “front”, “back”, “vertical”, “horizontal”, “top”, “bottom”, “inside”, “outside”, etc., indicating orientation or positional relationships are used to illustrate positional relationships between the composition elements, not to indicate or imply that involved devices or elements are required to have specific orientations and be structured and operated with the specific orientations but only to easily and simply describe the present specification, and thus should not be understood as limits to the present disclosure. The positional relationships between the constituent elements may be changed as appropriate according to a direction which is used for describing each constituent element. Therefore, appropriate replacements based on situations are allowed, not limited to the expressions in the specification.

In the specification, unless otherwise specified and defined, terms “mounting”, “mutual connection”, and “connection” should be generally understood. For example, the terms may be fixed connection, or detachable connection, or integral connection. The terms may be mechanical connection or electric connection. The terms may be direct connection, or indirect connection through an intermediate, or communication inside two elements. Those of ordinary skill in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It is to be noted that in the specification, the channel region refers to a main region that a current flows through.

In the specification, a first electrode may be the drain electrode, and a second electrode may be the source electrode. Alternatively, the first electrode may be a source electrode, and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode”, as well as the “source terminal” and the “drain terminal”, are interchangeable in the specification. In an embodiment of the present disclosure, the gate electrode may be referred to as a control electrode.

In the specification, “electric connection” includes connection of the composition elements through an element with a certain electric action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, other elements with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In an embodiment of the present disclosure, “about” refers to a value that is not strictly limited, the value within the range of process and measurement error is allowed.

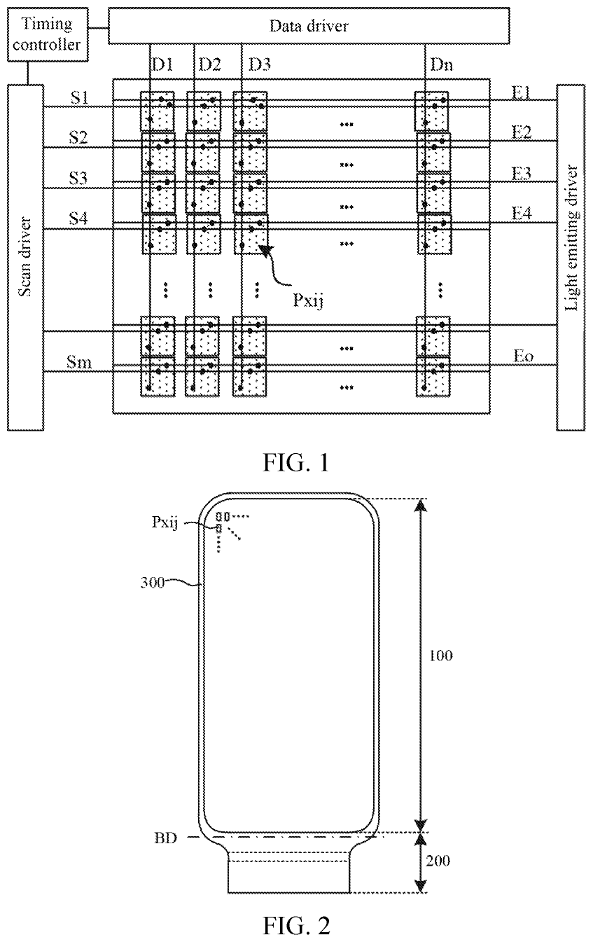

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, wherein i and j may be natural numbers, at least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide a grayscale value and a control signal suitable for the specification of the data signal driver to the data driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a row of pixels as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display region 100, a bonding region 200 located at a side of the display region 100, and a bezel region 300 located at another side of the display region 100. In an exemplary embodiment, the display region 100 may be a planar region including a plurality of sub-pixels Pxij that form a pixel array, the plurality of sub-pixels Pxij are configured to display a dynamic picture or a static image, and the display region 100 may be referred to as an Active Area (AA). In an exemplary embodiment, the display substrate may be a flexible substrate, so that the display substrate may be deformable, for example, curled, bent, folded, or rolled. In an exemplary embodiment, the display substrate may further include a display region boundary BD, which may be an edge of the display region 100 at a side close to the bonding region 200.

In an exemplary embodiment, the bonding region 200 may include a fan-out region, a bending region, a drive chip region, and a bonding pin region arranged sequentially along a direction away from the display region, wherein the fan-out region is connected to the display region and includes a plurality of data fan-out lines, and a data fan-out line is configured to connect a data signal line (Data Line) of the display region in a Fan-out line manner. The bending region is connected to the fan-out region and may include a composite insulation layer provided with a groove, and is configured to bend the bonding region to a back of the display region. The drive chip region may include an Integrated Circuit (IC for short) and is configured to be connected to the plurality of data fan-out lines. The bonding pin region may include a Bonding Pad, and is configured to be bonded to an external Flexible Printed Circuit board (FPC for short).

In an exemplary implementation, the bezel region 300 may include a circuit region, a power supply line region, and a crack dam region, and a cutting region which are sequentially arranged along the direction away from the display region. The circuit region is connected to the display region 100 and may at least include a gate drive circuit, and the gate drive circuit is connected to a first scan signal line, a second scan signal line, a third scan signal line, and a light emitting control line of a pixel drive circuit in the display region. The power supply line region is connected to the circuit region and may at least include a power supply lead line, and the power supply lead line extends along a direction parallel to an edge of the display region and is connected to a cathode in the display region. The crack dam region is connected to the power supply line region and may at least include a plurality of cracks arranged on the composite insulation layer. The cutting region is connected to the crack dam region and may at least include a cutting groove arranged on the composite insulation layer, and the cutting groove is configured that a cutting device can implement cutting along cutting grooves respectively after preparation of all film layers of the display substrate are completed.

In an exemplary implementation, the fan-out region in the bonding region 200 and the power supply line region in the bezel region 300 may be provided with a first isolation dam and a second isolation dam, the first isolation dam and the second isolation dam may extend along the direction parallel to the edge of the display region, thus forming an annular structure surrounding the display region, wherein the edge of the display region is an edge at a side of the display region, the bonding region, or the bezel region.

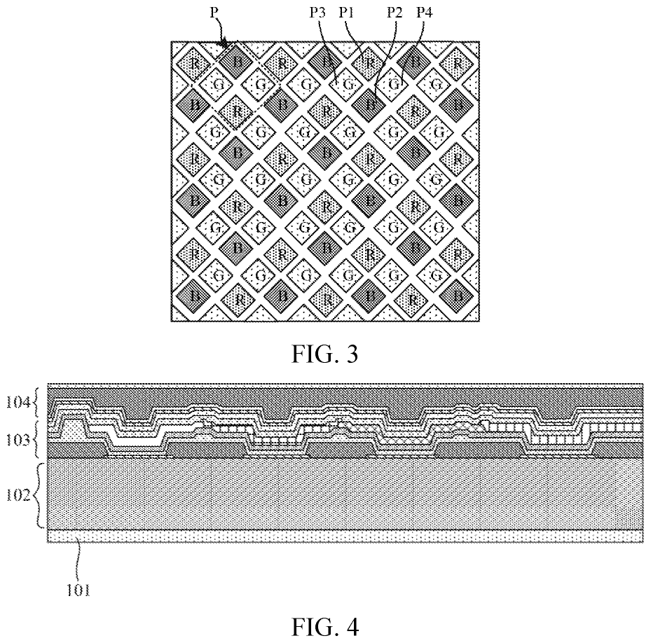

FIG. 3 is a schematic diagram of a planar structure of a display region in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 and a fourth sub-pixel P4 emitting light of a third color. Each sub-pixel may include a circuit unit and a light emitting device, wherein the circuit unit may at least include a pixel drive circuit which is connected to a scan signal line, a data signal line, and a light emitting signal line respectively, and the pixel drive circuit is configured to receive a data voltage transmitted by the data signal line and output a corresponding current to the light emitting device under control of the scan signal line and the light emitting signal line. The light emitting device in each sub-pixel is connected to a pixel drive circuit of a sub-pixel where the light emitting device is located, and is configured to emit light with corresponding brightness in response to a current output by the pixel drive circuit of the sub-pixel where the light emitting device is located.

In an exemplary implementation, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation, a shape of a sub-pixel may be a rectangle, a diamond, a pentagon, or a hexagon. The four sub-pixels may be arranged in a manner of diamond to form an RGBG pixel arrangement. In other exemplary implementations, the four sub-pixels may be arranged side by side horizontally, side by side vertically, or in a manner to form a square, which is not limited in the present disclosure.

In an exemplary implementation, a pixel unit may include three sub-pixels, and the three sub-pixels may be arranged side by side horizontally, side by side vertically, or in a manner like a Chinese character “ [symbol] ”, which is not limited here in the present disclosure.

FIG. 4 is a schematic diagram of a sectional structure of a display region in a display substrate, illustrating a structure of four sub-pixels in the display region. As shown in FIG. 4, on a plane perpendicular to the display substrate, the display substrate may include a drive circuit layer 102 arranged on a substrate 101, a light emitting structure layer 103 arranged on a side of the drive circuit layer 102 away from the substrate 101, and an encapsulation structure layer 104 arranged on a side of the light emitting structure layer 103 away from the substrate 101. In some possible implementations, the display substrate may include other film layers, such as a touch structure layer, etc., which is not limited here in the present disclosure.

In an exemplary implementation, the substrate 101 may be a flexible substrate, or may be a rigid substrate. The drive circuit layer 102 of each sub-pixel may include a pixel drive circuit formed by a plurality of transistors and a storage capacitor. The light emitting structure layer 103 of each sub-pixel may include a light emitting device formed by a plurality of film layers, wherein the plurality of film layers may at least include an anode, a pixel definition layer, an organic emitting layer, and a cathode. The anode is connected to the pixel drive circuit, the organic emitting layer is connected to the anode, the cathode is connected to the organic emitting layer, and the organic emitting layer emits light of a corresponding color under drive of the anode and the cathode. The encapsulation layer 104 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of an inorganic material/an organic material/an inorganic material and ensure that external water vapor cannot enter the light emitting structure layer 103.

In an exemplary implementation, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more layers of hole injection layers, hole transport layers, electron block layers, hole block layers, electron transport layers, and electron injection layers of all sub-pixels may be a common layer connected together. Emitting layers of adjacent sub-pixels may be overlapped slightly, or may be isolated from each other.

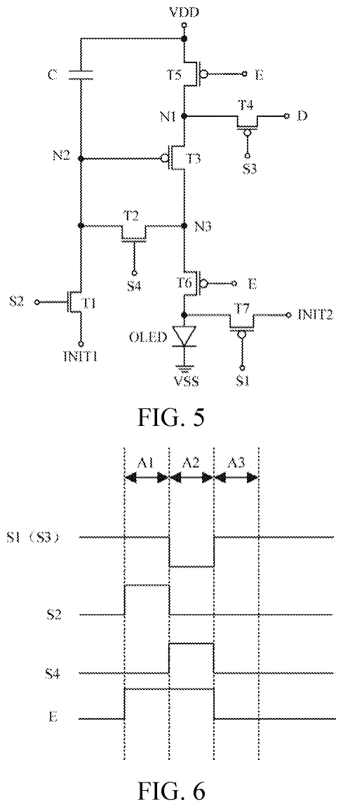

FIG. 5 is a schematic diagram of an equivalent circuit of a pixel drive circuit. In an exemplary implementation, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7) and one storage capacitor C, and the pixel drive circuit is respectively connected to ten signal lines (a data signal line D, a first scan signal line S1, a second scan signal line S2, a third scan signal line S3, a fourth scan signal line S4, a light emitting signal line E, a first initial signal line INIT1, a second initial signal line INIT1, a first power supply line VDD, and a second power supply line VSS).

In an exemplary implementation, the pixel drive circuit may include a first node N1, a second node N2, and a third node N3. Among them, the first node N1 is respectively connected to a first electrode of the third transistor T3, a second electrode of the fourth transistor T4, and a second electrode of the fifth transistor T5, the second node N2 is respectively connected to a second electrode of the first transistor T1, a control electrode of the third transistor T3, and a second end of the storage capacitor C, and the third node N3 is respectively connected to a second electrode of the second transistor T2, a second electrode of the third transistor T3, and a first electrode of the sixth transistor T6.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

In an exemplary implementation, a control electrode of the first transistor T1 is connected to the second scan signal line S2, a first electrode of the first transistor T1 is connected to the first initial signal line INIT1, and the second electrode of the first transistor T1 is connected to the second node N2. When a turned-on scan signal is applied to the second scan signal line S2, the first transistor T1 transmits a first initialization voltage to the second end of the storage capacitor C to initialize the storage capacitor C.

In an exemplary implementation, a control electrode of the second transistor T2 is connected to the fourth scan signal line S4, a first electrode of the second transistor T2 is connected to the second electrode of the first transistor T1, and the second electrode of the second transistor T2 is connected to the third node N3. When a turned-on scan signal is applied to the fourth scan signal line S4, the second transistor T2 enables the control electrode of the third transistor T3 to be connected to the second electrode of the third transistor T3.

In an exemplary implementation, the control electrode of the third transistor T3 is connected to the second node N2, namely the control electrode of the third transistor T3 is connected to the second end of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines a size of a drive current flowing between the first power supply line VDD and a light emitting device according to a potential difference between the control electrode and the first electrode of the third transistor T3.

In an exemplary implementation, a control electrode of the fourth transistor T4 is connected to the third scan signal line S3, a first electrode of the fourth transistor T4 is connected to the data signal line D, and the second electrode of the fourth transistor T4 is connected to the first node N1. When a turned-on scan signal is applied to the third scan signal line S3, the fourth transistor T4 enables a data voltage of the data signal line D to be input to the first node N1.

In an exemplary implementation, a control electrode of the fifth transistor T5 is connected to the light emitting signal line E, a first electrode of the fifth transistor T5 is connected to the first power supply line VDD, and the second electrode of the fifth transistor T5 is connected to the first node N1. The control electrode of the sixth transistor T6 is connected to the light emitting signal line E, the first electrode of the sixth transistor T6 is connected to the third node N3, and the second electrode of the sixth transistor T6 is connected to the first electrode of the light emitting device. When a turned-on light emitting signal is applied to the light emitting signal line E, the fifth transistor T5 and the sixth transistor T6 enable the light emitting device to emit light by forming a drive current path between the first power supply line VDD and the light emitting device.

In an exemplary implementation, a control electrode of the seventh transistor T7 is connected to the first scan signal line S1, a first electrode of the seventh transistor T7 is connected to the second initial signal line INIT2, and a second electrode of the seventh transistor T7 is connected to the first electrode of the light emitting device. When a turned-on scan signal is applied to the first scan signal line S1, the seventh transistor T7 transmits a second initial voltage to the first electrode of the light emitting device so as to initialize a charge amount accumulated in the first electrode of the light emitting device or release a charge amount accumulated in the first electrode of the light emitting device.

In an exemplary implementation, the light emitting device may be an OLED including a first electrode (anode), an organic emitting layer, and a second electrode (cathode) which are stacked, or may be a QLED including a first electrode (anode), a quantum dot emitting layer, and a second electrode (cathode) which are stacked.

In an exemplary implementation, the second electrode of the light emitting device is connected to the second power supply line VSS, a signal of the second power supply line VSS is a low-level signal, and a signal of the first power supply line VDD is a high-level signal continuously provided.

In an exemplary implementation, the first transistor T1 to the seventh transistor T7 may be P-type transistors or N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first transistor T1 to the seventh transistor T7 may be low-temperature polysilicon transistors, or may be oxide transistors, or may be both of low-temperature polysilicon transistors and metal oxide transistors. Low Temperature Poly-Silicon (LTPS for short) is adopted for an active layer of a low temperature polysilicon transistor and a metal oxide semiconductor (Oxide) is adopted for an active layer of a metal oxide transistor. A low temperature polysilicon transistor has advantages such as a high migration rate and fast charging, and an oxide transistor has advantages such as a low drain current. The low temperature polysilicon transistor and the metal oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

FIG. 6 is a working timing diagram of a pixel drive circuit. An exemplary embodiment of the present disclosure will be described below through a working process of the pixel drive circuit exemplified in FIG. 5. The pixel drive circuit in FIG. 5 includes seven transistors (a first transistor T1 to a seventh transistor T7) and one storage capacitor C, wherein the first transistor T1 and the second transistor T2 are N-type oxide transistors, and the third transistor T3 to the seven transistor T7 are P-type low-temperature polysilicon transistors. In an exemplary implementation, the working process of the pixel drive circuit may include following stages.

In a first stage A1, which is referred to as a reset stage, a signal of the second scan signal line S2 is a turned-on signal (high-level), and signals of the first scan signal line S1, the third scan signal line S3, the fourth scan signal line S4, and the light emitting signal line E are turned-off signals. The turned-on signal of the second scan signal line S2 enables the first transistor T1 to be turned on, and a signal of the first initial signal line INIT1 is provided to the second node N2 through the first transistor T1 to initialize (reset) the storage capacitor C, thereby clearing an original charge in the storage capacitor. The turned-off signals of the first scan signal line S1, the third scan signal line S3, the fourth scan signal line S4, and the light emitting signal line E enable the second transistor T2, the fourth transistor T4, the fifth transistor T5, the sixth transistor T6, and the seventh transistor T7 to be turned off, and an OLED does not emit light in this stage.

In a second stage A2, referred to as a data writing stage or a threshold compensation stage, signals of the first scan signal line S1, the third scan signal line S3, and the fourth scan signal line S4 are turned-on signals, signals of the second scan signal line S2 and the light emitting signal line E are turned-off signals, and the data signal line D outputs a data voltage. In this stage, the second end of the storage capacitor C is at a low level, so the third transistor T3 is turned on. The turned-on signals of the first scan signal terminal S1, the third scan signal terminal S3, and the fourth scan signal terminal S4 enable the second transistor T2, the fourth transistor T4, and the seventh transistor T7 to be turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd-|Vth|, wherein Vd is the data voltage output by the data signal line D, and Vth is the threshold voltage of the third transistor T3. The seventh transistor T7 is turned on, so that a signal of the second initial signal line INIT2 is provided to a first electrode of the OLED to initialize (reset) the first electrode of the OLED and clear its internal pre-stored voltage, thereby completing initialization and ensuring that the OLED does not emit light. A turned-off signal of the second scan signal line S2 enables the first transistor T1 to be turned off, and a turned-off signal of the light emitting signal line E enables the fifth transistor T5 and the sixth transistor T6 to be turned off.

In a third stage A3, referred to as a light emitting stage, a signal of the light emitting signal line E is a turned-on signal, and signals of the first scan signal line S1, the second scan signal line S2, the third scan signal line S3, and the fourth scan signal line S4 are turned-off signals. The turned-on signal of the light emitting signal line E enables the fifth transistor T5 and the sixth transistor T6 to be turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata-|Vth|, so the drive current of the third transistor T3 is as follows.

$$I = K * {( Vgs - Vth )}^{2} = K * {[ ( Vdd - Vd + \vert Vth \vert ) - Vth ]}^{2} = K * {[ ( Vdd - Vd ) ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With the development of OLED display technology, the requirements for the display quality of OLED display products are getting higher and higher. The 7T1C or 6T1C used in a pixel drive circuit gradually changes from one initial signal line to two initial signal lines, that is, the gate electrode of the drive transistor and the anode of the light emitting element are respectively initialized by signals of separate initial signal lines, so that the initial signals required by the drive transistor and the anode of the light emitting element can be adjusted separately. For example, the signal of the initial signal line controlling the drive transistor is set to −3V, and the signal of the initial signal line controlling the anode of the light emitting element is set to −4V, which can not only meet the requirement of 0 gray scale, but also meet the brightness required in a high brightness mode. The reasons why the initial signal lines are set are that, on the one hand, there is a voltage drop on the initial signal line, and the voltage drop on the initial signal line will easily cause unevenness of picture display in the working process of the pixel drive circuit; and on the other hand, the pixel size is usually about tens of microns, and adding a signal line in the pixel drive circuit sets a high challenge for the process, which requires line width and spacing to be reduced accordingly.

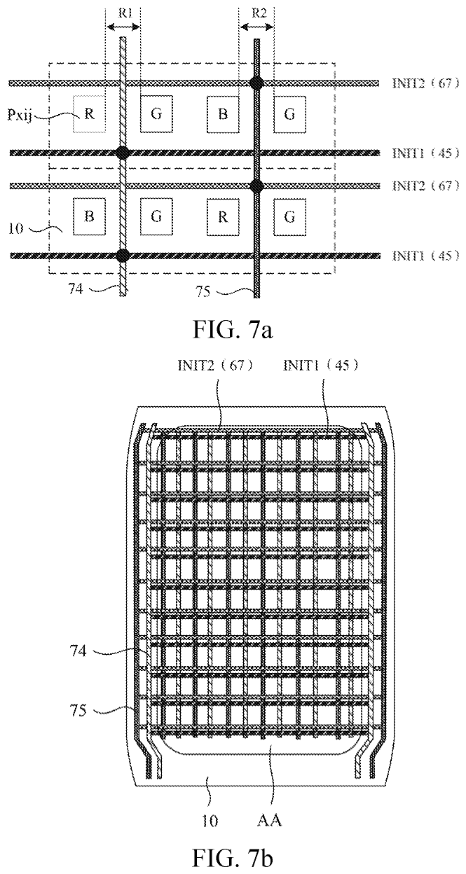

An exemplary embodiment of the present disclosure provides a display substrate, as shown in FIG. 7, including a substrate 10, wherein a plurality of initial signal lines INIT and K rows and L columns of sub-pixels are provided on the substrate 10, K and L are each a positive integer greater than 1; a plurality of pixel column spaces R (R1, R2) are included between L pixel columns, the pixel column space R is located between two adjacent pixel columns; at least one of the pixel column spaces is provided with initial signal connection lines (74, 75), at least one of the initial signal connection lines is electrically connected to the plurality of initial signal lines R through a via hole, on a plane parallel to the display substrate, the plurality of initial signal lines INIT (INIT1, INIT2) extend in a first direction X and are arranged in a second direction Y, the initial signal connection lines (74, 75) extend in the second direction, and the first direction X intersects the second direction Y.

For the display substrate provided by an embodiment of the present disclosure, the display substrate includes a substrate on which a plurality of initial signal lines and K rows and L columns of sub-pixels are provided, K and L being each a positive integer greater than 1; a plurality of pixel column spaces are included between L pixel columns, the pixel column space is located between two adjacent pixel columns; at least one of the pixel column spaces is provided with initial signal connection lines, at least one of the initial signal connection lines is electrically connected to the plurality of initial signal lines through a via hole; the initial signal connection lines are disposed in the pixel column spaces, and the plurality of initial signal lines are connected through the initial signal connection lines, which reduces the voltage drop of the initial signal lines without increasing the process difficulty, and improves display uniformity.

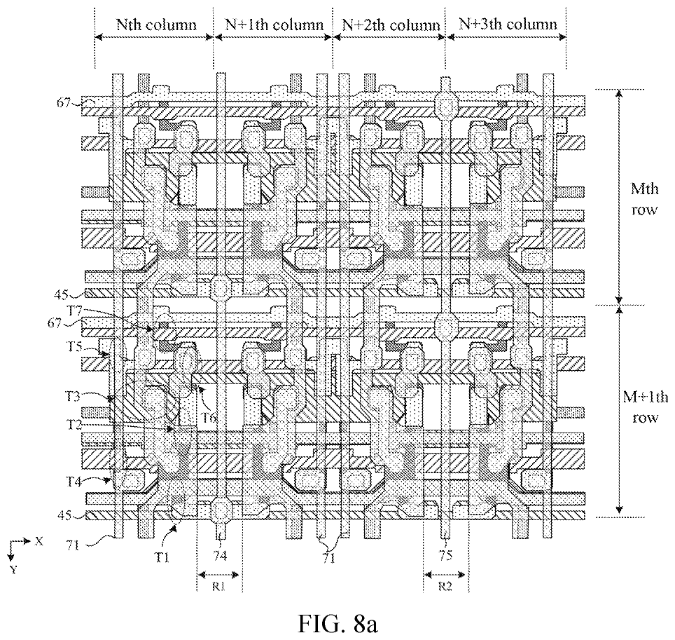

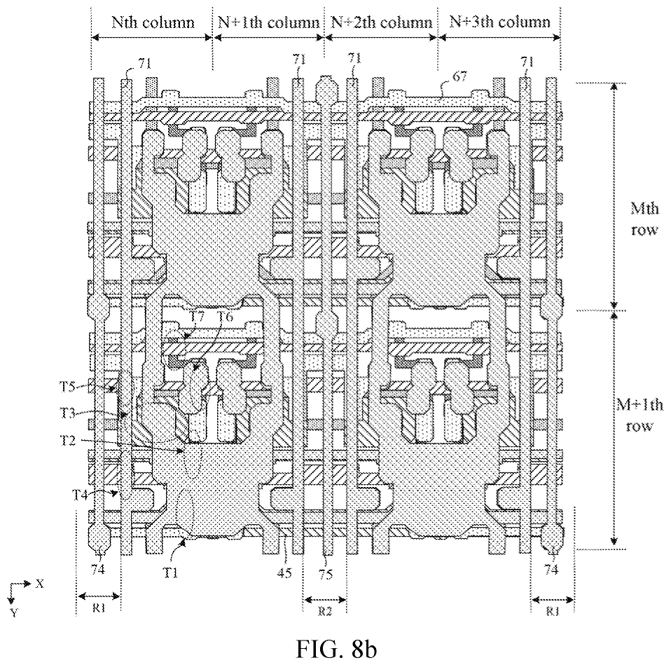

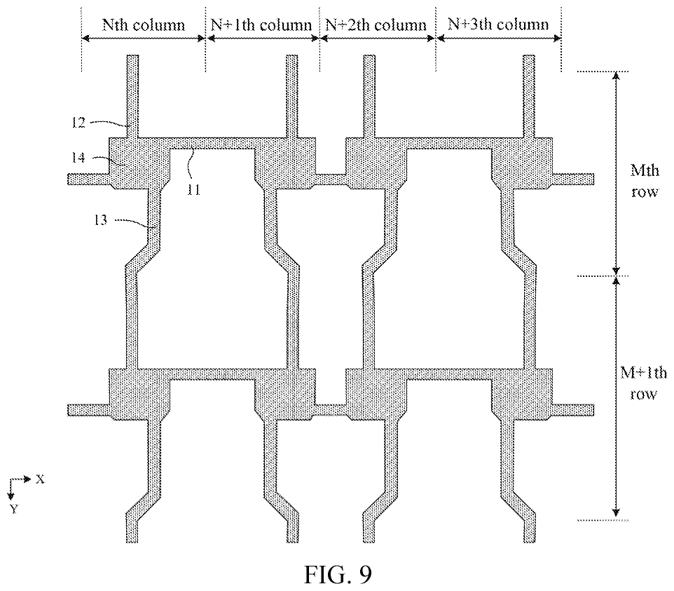

In an exemplary implementation, as shown in FIGS. 7 and 8, the plurality of pixel column spaces R include a plurality of first pixel column spaces R1 and a plurality of second pixel column spaces R2, orthographic projections of the first pixel column spaces R1 and the second pixel column spaces R2 on the substrate do not overlap;

the initial signal line INIT includes a first initial signal line INIT1 (45) and a second initial signal line INIT2 (67), the initial signal connection line includes a first initial signal connection line 74 and a second initial signal connection line 75, the first initial signal connection line 74 is disposed in the first pixel column space R1, the second initial signal connection line 75 is disposed in the second pixel column space R2, the first initial signal connection line 74 is electrically connected to the first initial signal line 45 through a via hole, and the second initial signal connection line 75 is electrically connected to the second initial signal line 67 through a via hole.

As shown in FIG. 7, the first initial signal lines 45 and the first initial signal connection lines 74 are connected to each other to form a grid shape, and the plurality of first initial signal lines 45 are connected as a whole by the first initial signal connection lines 74, which reduces a voltage drop on the first initial signal lines 45; the second initial signal lines 67 and the second initial signal connection lines 75 are connected to each other to form a grid shape, and the plurality of second initial signal lines 67 are connected as a whole by the second initial signal connection lines 75, which reduces a voltage drop on the second initial signal lines 67 and greatly improves display uniformity. FIG. 7a is a partially enlarged structural schematic diagram of FIG. 7b, AA in FIG. 7b being a display region.

In an exemplary implementation, as shown in FIG. 8, L data signal lines 71 corresponding to L pixel columns respectively are further provided on the substrate, on a plane parallel to the display substrate, the L data signal lines 71 extend in the second direction Y and are arranged in the first direction X, in the first direction X, any one of the data signal lines 71 is located at a side of a corresponding pixel column.

On a plane parallel to the display substrate, in the first direction X, the pixel column space is located at a side of the data signal line 71 away from the corresponding pixel column, the pixel column space is located between two adjacent data signal lines 71, as shown in FIG. 8b; or as shown in FIG. 8a, the pixel column space is located at a side of the pixel column away from the corresponding data signal line 71, and the pixel column space is located between two adjacent pixel columns. In the structure shown in FIG. 8b, the initial signal connection line is located between two adjacent data signal lines 71, which can ensure the integrity of graphics for covering the control electrodes of the oxide transistors T1, T2 and the drive transistor T3, improve the shielding and covering effect, and improve the PPI of the display product. This scheme has great advantages in the design of high PPI display products.

In an exemplary implementation, in a plane perpendicular to the display substrate, the display substrate includes a substrate, and a first semiconductor layer, a first conductive layer, a second conductive layer, a second semiconductor layer, a third conductive layer, a fourth conductive layer and a fifth conductive layer that are sequentially stacked on the substrate.

The first semiconductor layer at least includes active layers of a plurality of low temperature polysilicon transistors; the first conductive layer at least includes control electrodes of the plurality of low temperature polysilicon transistors, and a first plate of a storage capacitor; the second conductive layer at least includes a second plate of the storage capacitor and the first initial signal lines 45; the second semiconductor layer at least includes active layers of a plurality of oxide transistors; the third conductive layer at least includes control electrodes of the plurality of oxide transistors; the fourth conductive layer at least includes first electrodes and second electrodes of the plurality of polysilicon transistors, first electrodes and second electrodes of the plurality of oxide transistors, and the second initial signal lines 67; and the fifth conductive layer at least includes the first initial signal connection lines 74 and the second initial signal connection lines 75.

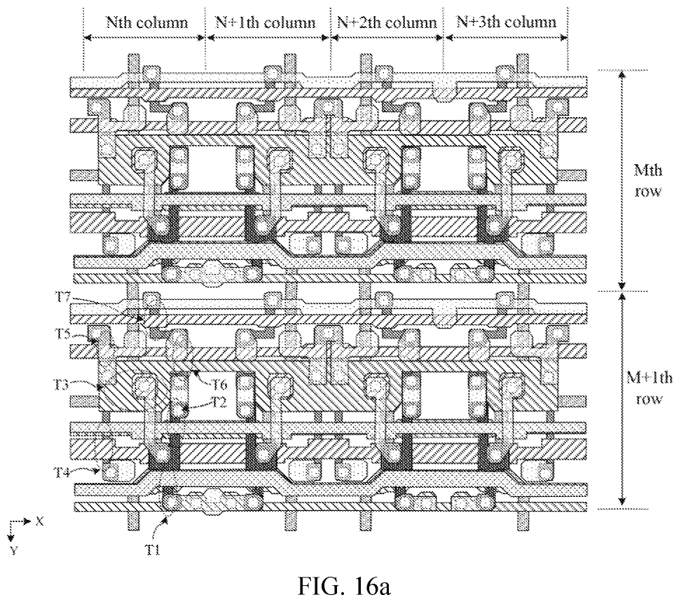

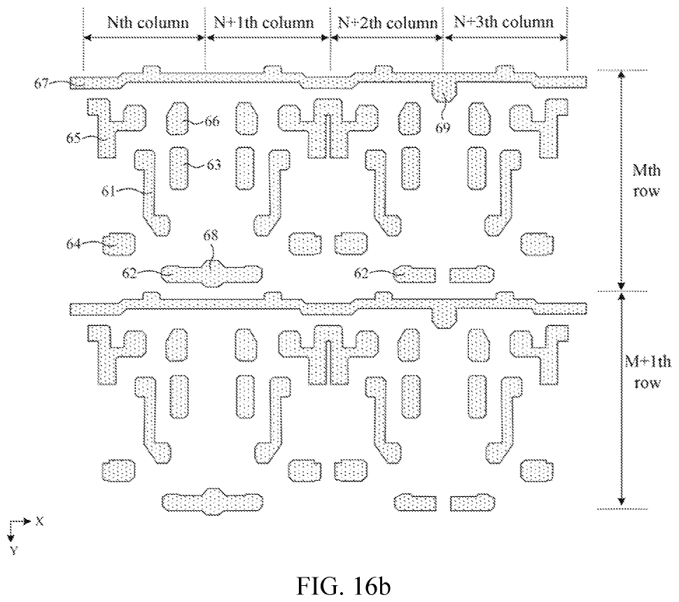

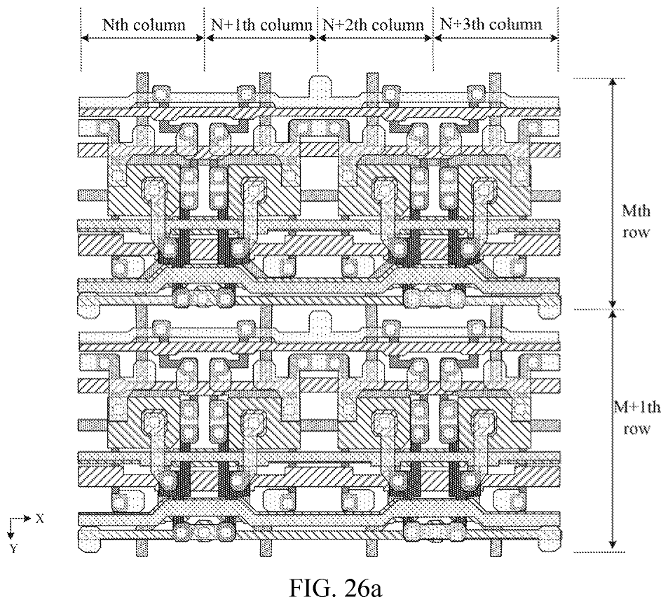

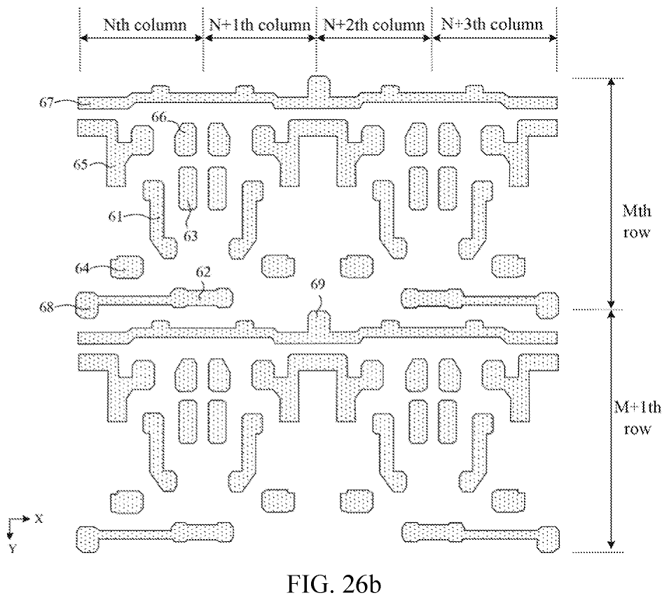

In an exemplary implementation, as shown in FIGS. 16 and 26, the fourth conductive layer further includes a first initial signal connection electrode 68 and a second initial signal connection electrode 69, the second initial signal connection electrode 69 and the second initial signal line 67 are an integrally molded structure; the first initial signal connection electrode 68 is electrically connected to the first initial signal line 45 and the first initial signal connection line 74 respectively through different via holes, and the second initial signal connection line 75 is electrically connected to the second initial signal connection electrode 69 through a via hole.

In an exemplary implementation, as shown in FIGS. 16 and 26, the plurality of low temperature polysilicon transistors include a first transistor T1 as a first initialization transistor, and a first electrode of the first transistorT1 and the first initial signal connection electrode 68 are an integrally molded structure.

In an exemplary implementation, as shown in FIGS. 8b and 26, L data signal lines 71 corresponding to L pixel columns respectively are further provided on the substrate, on a plane parallel to the display substrate, the L data signal lines 71 extend in the second direction Y and are arranged in the first direction X, in the first direction X, any one of the data signal lines 71 is located at a side of a corresponding pixel column.

On a plane parallel to the display substrate, in the first direction X, the pixel column space is located at a side of the data signal line 71 away from a corresponding pixel column, the pixel column space is located between two adjacent data signal lines 71, the first pixel column space R1 and the second pixel column space R2 are alternately arranged in the first direction X, two columns of sub-pixels are provided between two adjacent pixel column spaces, first electrodes of two first transistors T1 located between two adjacent pixel column spaces are an integrally molded structure, the first initial signal connection electrode 68 extends in the first direction X, one end of the first initial signal connection electrode 68 is provided with an electrode connection block 681, the other end of the first initial signal connection electrode 68 is connected to the integrally molded first electrodes of the two first transistors T1, and there is an overlapping area between an orthographic projection of the electrode connection block 681 on the substrate and an orthographic projection of the first column of pixel spaces on the substrate.

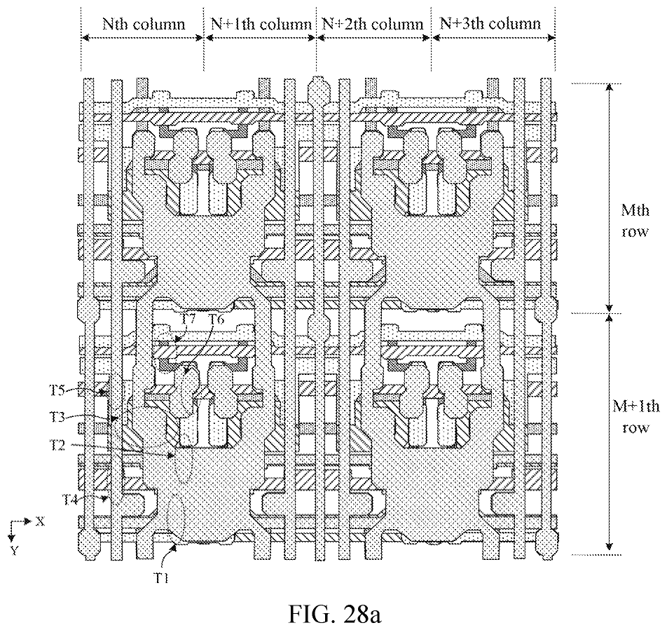

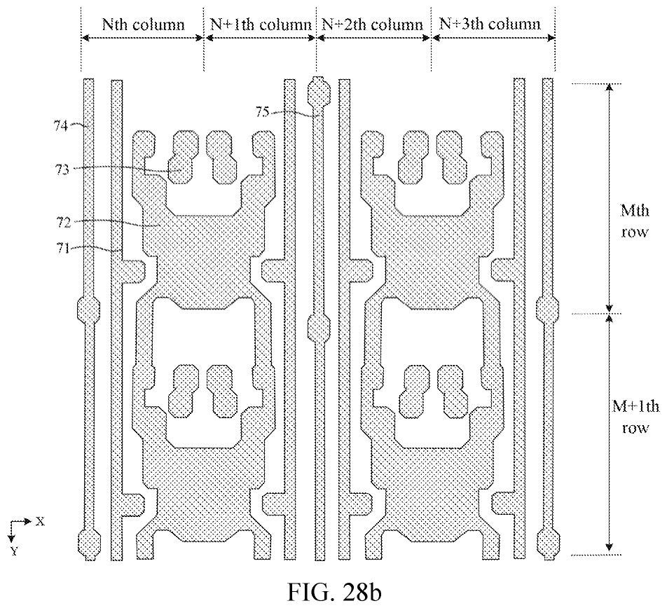

In an exemplary implementation, as shown in FIG. 28, a first power supply line 72 is further provided on the fifth conductive layer, the first power supply line 72 is electrically connected to the second plate through a via hole, the first power supply lines 72 in a same pixel column are an integrally molded structure, and the first power supply lines 72 corresponding to two columns of pixels located between two adjacent pixel column spaces are an integrally molded structure.

In an exemplary implementation, as shown in FIGS. 8b and 16, L data signal lines 71 corresponding to L pixel columns respectively are further provided on the substrate, on a plane parallel to the display substrate, the L data signal lines 71 extend in the second direction Y and are arranged in the first direction X, in the first direction X, any one of the data signal lines 71 is located at a side of a corresponding pixel column.

On a plane parallel to the display substrate, in the first direction X, the pixel column space is located at a side of the pixel column away from a corresponding data signal line 71, the pixel column space is located between two adjacent pixel columns, the first pixel column space R1 and the second pixel column space R2 are alternately arranged in the first direction X, two columns of sub-pixels are provided between two adjacent pixel column spaces, the first initial signal connection electrode 68 and first electrodes of two first transistors T1 located on both sides of the first pixel column space R1 are an integrally molded structure, and there is an overlapping area between an orthographic projection of the first initial signal connection electrode 68 on the substrate and an orthographic projection of the first column of pixel spaces on the substrate.

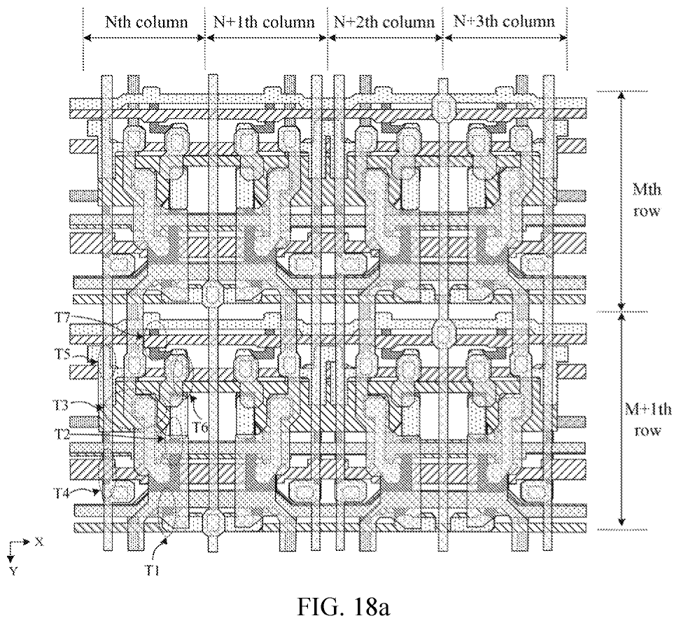

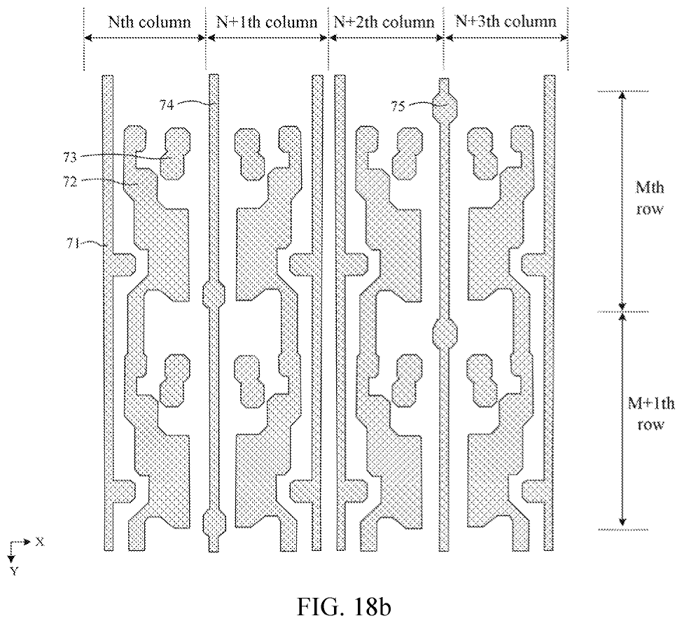

In an exemplary implementation, as shown in FIG. 18, a first power supply line 72 is further provided on the fifth conductive layer, the first power supply line 72 is electrically connected to the second plate through a via hole, and the first power supply lines 72 in a same pixel column form an integrally molded structure.

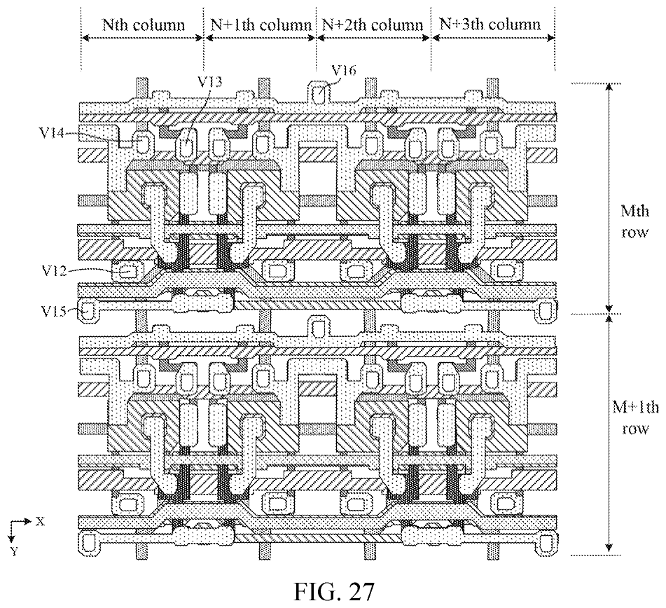

In an exemplary implementation, as shown in FIGS. 26, 27, 16 and 17, the first electrode of the first transistor T1 is electrically connected to the active layer of the first transistor T1 and the first initial signal line 45 through different via holes, respectively, and the first initial signal connection electrode 68 is electrically connected to the first initial signal connection line 74 through a via hole. In an embodiment of the present disclosure, in a structure in which the first electrode of the first transistor T1 and the electrode connection block are integrally molded, the first initial signal connection electrode 68 may be reused into the first electrode of the first transistor T1.

In an exemplary implementation, as shown in FIG. 8, at least one sub-pixel includes a pixel drive circuit electrically connected to the initial signal line, the pixel drive circuit at least includes a plurality of transistors, and the plurality of transistors at least include a first transistor T1 as a first initialization transistor and a seventh transistor T7 as a second initialization transistor; a first electrode of the first transistor T1 is electrically connected to the first initial signal line 45, and a first electrode of the seventh transistor T7 is electrically connected to the second initial signal line 67.

In an exemplary implementation, the pixel drive circuit further includes a storage capacitor electrically connected to a second electrode of the first transistor T1, on a plane parallel to the display substrate, in the second direction Y, the first transistor T1 and the seventh transistor T7 are located on both sides of the storage capacitor, and the first initial signal line 45 and the second initial signal line 67 are located on both sides of the storage capacitor.

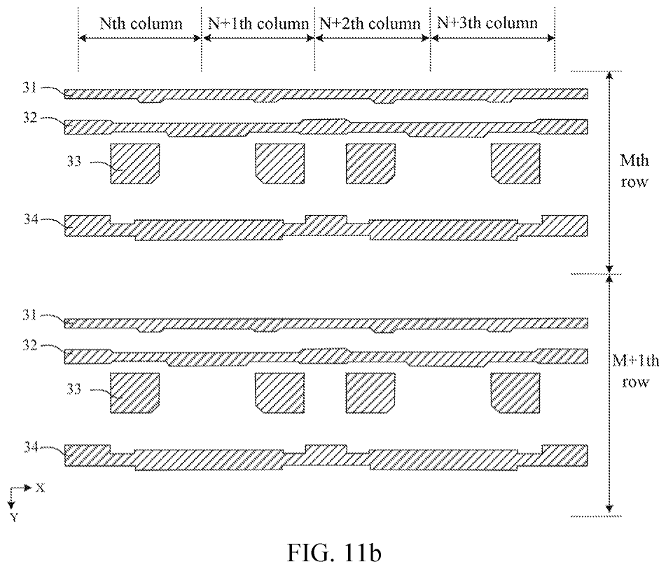

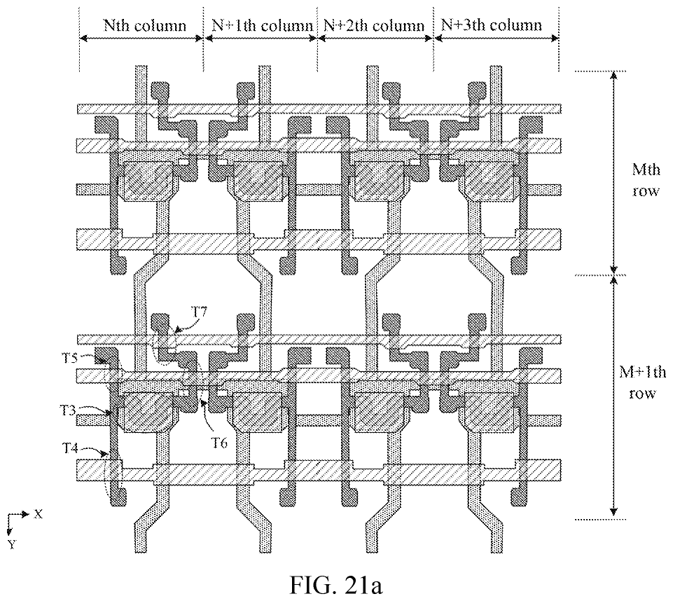

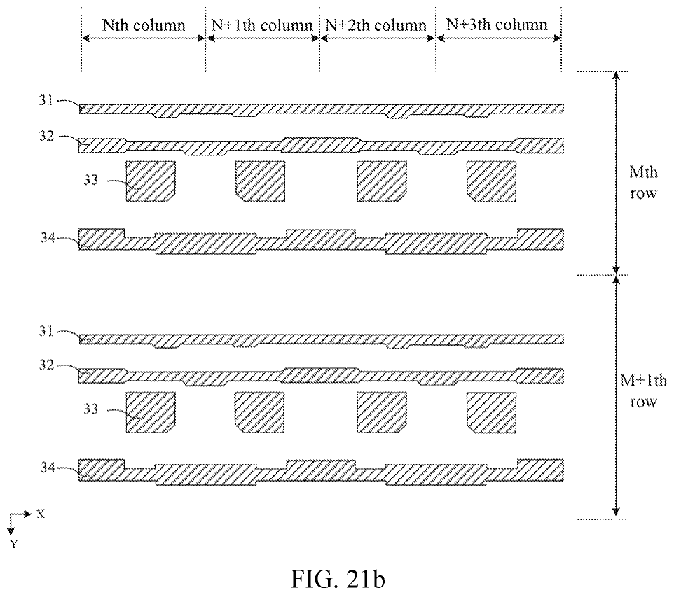

In an exemplary implementation, as shown in FIGS. 11 and 21, the plurality of transistors further include a fourth transistor T4 as a data writing transistor, a plurality of scan signal lines extending in the first direction X are further provided on the substrate, the plurality of scan signal lines at least include a first scan signal line 31 and a third scan signal line 34, the first scan signal line 31 serves as a control electrode of the seventh transistor T7, and the third scan signal line 34 serves as a control electrode of the fourth transistor T4; on a plane parallel to the substrate, in the second direction Y, orthographic projections of the first scan signal line 31 and the third scan signal line 34 on the substrate are located on both sides of an orthographic projection of the storage capacitor on the substrate.

In an embodiment of the present disclosure, the first scan signal line 31 and the third scan signal line 34 are used as control electrodes of the seventh transistor T7 and the fourth transistor T4, respectively, which, compared with the scheme in which a same scan signal line is used as control electrodes of the fourth transistor T4 and the seventh transistor T7, can reduce a load on the third scan signal line 34 that serves as the control electrode of the fourth transistor T4, and reduce a rise time (Tr) and a fall time (Tf) of a potential change when the fourth transistor T4 is turned off and turned on. Because the fourth transistor T4 controls writing of a potential of the control electrode of the drive transistor T3, the Tr/Tf of the potential change when the fourth transistor T4 is turned off and turned on is reduced, so that a potential charging rate of the driver transistor T3 is enhanced, thereby further improving display uniformity.

In an exemplary implementation, as shown in FIGS. 8, 11, 14, 21 and 24, the plurality of transistors further include a second transistor T2 as a compensation transistor, a fifth transistor T5 and a sixth transistor T6 as light emitting transistors, the plurality of scan signal lines further include a second scan signal line 51, a fourth scan signal line 52 and a light emitting control line 32, the second scan signal line 51 serves as a control electrode of the first transistor T1, the fourth scan signal line 52 serves as a control electrode of the second transistor T2, and the light emitting control line 32 serves as a control electrode of the fifth transistor T5 and the sixth transistor T6; in a same pixel row, in a plane where the display substrate is located, the second initial signal line 67, the first scan signal line 31, the light emitting control line 32, the storage capacitor, the fourth scan signal line 52, the third scan signal line 34, the second scan signal line 51 and the first initial signal line 45 are sequentially arranged in the second direction Y.

In an exemplary implementation, as shown in FIG. 8, the plurality of transistors further include a third transistor T3 as a drive transistor, and there is an overlapping area between an orthographic projection of the third transistor T3 on the substrate and an orthographic projection of the storage capacitor on the substrate.

In an exemplary implementation, the first transistor T1 and the second transistor T2 are oxide transistors, and the third transistor T3 to the seventh transistor T7 are low temperature polysilicon transistors.

Exemplary description is made below through a preparation process for a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a material on a substrate (or base substrate) using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, taking 8 sub-pixels (2 pixel rows, 4 pixel columns) as an example, a preparation process for a display substrate may include the following operations.

(101) A substrate is prepared on a glass carrier plate. In an exemplary implementation, the substrate may be a flexible substrate, or a rigid substrate. The rigid substrate may include, but is not limited to, one or more of glass and quartz. The flexible substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible substrate may include a first flexible material layer, a first inorganic material layer, a semiconductor layer, a second flexible material layer and a second inorganic material layer stacked on the glass carrier plate. Materials of the first flexible material layer and the second flexible material layer may be Polyimide (PI), Polyethylene Terephthalate (PET), or surface treated polymer soft film, etc., and materials of the first inorganic material layer and the second inorganic material layer may be Silicon Nitride (SiNx), Silicon Oxide (SiOx), or the like, for improving water and oxygen resistance of a substrate. The first inorganic material layer and the second inorganic material layer may also be referred to as barrier layers. The material of the semiconductor layer may be amorphous silicon (a-si). In an exemplary implementation, taking a stacked structure of PI1/Barrier1/a-si/PI2/Barrier2 as an example, its manufacturing process may include: first coating a layer of polyimide on a glass carrier board, after the layer of polyimide is cured to form a film, a first flexible material (PI1) layer is formed; then depositing a layer of barrier thin film on the first flexible layer to form a first barrier (Barrier 1) layer overlaying the first flexible material layer; then depositing a layer of amorphous silicon thin film on the first barrier layer to form an amorphous silicon (a-si) layer overlaying the first barrier layer; then coating another layer of polyimide on the amorphous silicon layer, after this layer of polyimide is cured to form a film, a second flexible material (PI2) layer is formed; and then depositing a layer of barrier thin film on the second flexible layer to form a second barrier (Barrier 2) layer overlaying the second flexible layer, so as to complete the preparation of the substrate.

(102) A pattern of a shielding layer is formed. In an exemplary implementation, forming the pattern of the shielding layer may include: depositing a first conductive thin film on the substrate, and patterning the first conductive thin film through a patterning process, to form the pattern of the shielding layer on the substrate, as shown in FIG. 9, which is a diagram of a planar structure of the pattern of the shielding layer in eight sub-pixels.

In an exemplary implementation, the pattern of the shielding layer of each sub-pixel may include a first shielding structure 11, a second shielding structure 12, a third shielding structure 13 and a shielding block 14. A shape of the shielding block 14 may be rectangle, and the corners of the rectangular may be chamfered. The first shielding structure 11 may be in a shape of a strip extending in the first direction X, and the first shielding structure 11 is disposed at a side of the shielding block 14 in the first direction X and connected to the shielding block 14. The second shielding structure 12 may be in a shape of a strip extending in the second direction Y, and the second shielding structure 12 is disposed at a side of the shielding block 14 in an opposite direction of the second direction Y and connected to the shielding block 14. The third shielding structure 13 may be in a shape of a bend line extending in the second direction Y, and the third shielding structure 13 is disposed at a side of the shielding block 14 in the second direction Y and connected to the shielding block 14.

In an exemplary implementation, the first shielding structure 11 of each sub-pixel is connected to the shielding blocks 14 of adjacent sub-pixels in the first direction X such that the shielding layers in a sub-pixel row are connected as a whole to form an interconnected integral structure.

In an exemplary implementation, the second shielding structure 12 of each sub-pixel is connected to the third shielding structures 13 of adjacent sub-pixels in the second direction Y such that the shielding layers in a sub-pixel column are connected as a whole to form an interconnected integral structure.

In an exemplary implementation, the shielding layers in a sub-pixel row and a sub-pixel column are connected as a whole, which may ensure that the shielding layers in the display substrate have a same potential, and this is beneficial to improving uniformity of a panel, avoiding display defect of the display substrate, and ensuring a display effect of the display substrate.

In an exemplary implementation, the shielding layers of the Nth column and the shielding layers of the (N+1)th column may be mirror symmetrical with respect to a first center line, the shielding layers of the (N+1)th column and the shielding layers of the (N+2)th column may be mirror symmetrical with respect to a second center line, the shielding layers of the (N+2)th column and the shielding layers of the (N+3)th column may be mirror symmetrical with respect to a third center line, and the first, second and third center lines may respectively be straight lines between adjacent sub-pixel columns and extended in the second direction Y.

In an exemplary implementation, shapes of the shielding layers in a plurality of sub-pixel rows may be the same.

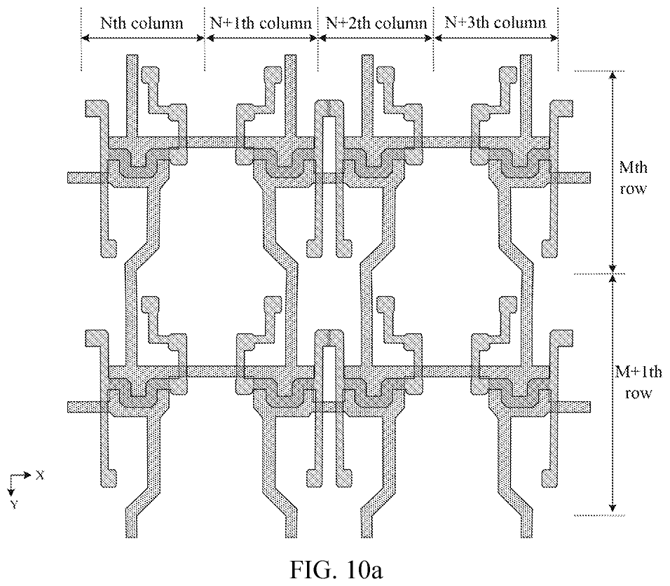

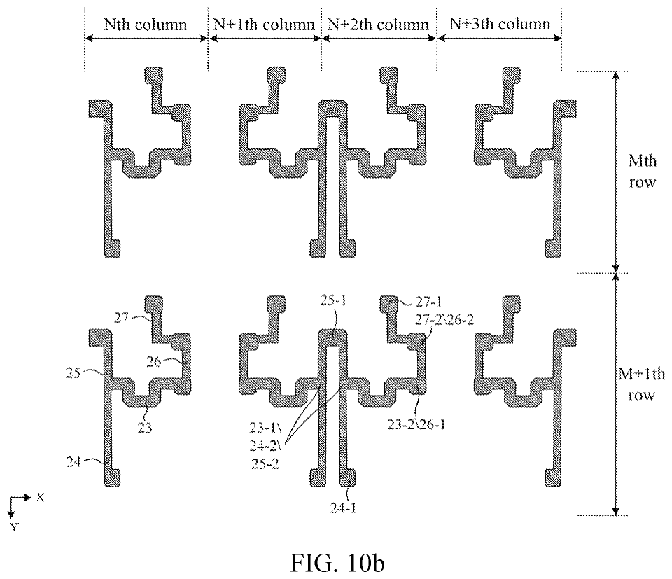

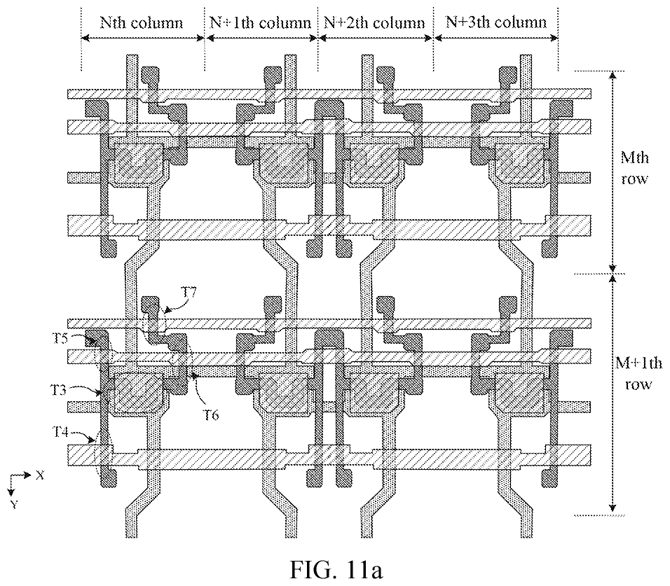

(103) A pattern of a first semiconductor layer is formed. In an exemplary implementation, forming the pattern of the first semiconductor layer may include: depositing sequentially a first insulation thin film and a first semiconductor thin film on the substrate on which the aforementioned pattern is formed, and patterning the first semiconductor thin film through a patterning process to form a first insulation layer covering the pattern of the shielding layer, and the pattern of the first semiconductor layer disposed on the first insulation layer, as shown in FIG. 10, wherein FIG. 10a is a diagram of a planar structure of eight sub-pixels, and FIG. 10b is a planar schematic view of a first semiconductor layer in FIG. 10a.

In an exemplary implementation, the pattern of the first semiconductor layer of each sub-pixel may include the active layer 23 of the third transistor T3 to the active layer 27 of the seventh transistor T7, and the active layer 23 of the third transistor T3 to the active layer 27 of the seventh transistor T7 are connected to each other to form an integrated structure.

In an exemplary implementation, in the first direction X, the active layer 24 of the fourth transistor T4 and the active layer 25 of the fifth transistor T5 are located at a same side of the active layer 23 of the third transistor T3, and the active layer 26 of the sixth transistor T6 is located at the other side of the active layer 23 of the third transistor T3; and in the second direction Y, the active layer 24 of the fourth transistor T4 and the active layer 25 of the fifth transistor T5 are located on both sides of the active layer 23 of the third transistor T3, the active layer 25 of the fifth transistor T5, the active layer 26 of the sixth transistor T6 and the active layer 27 of the seventh transistor T7 are located at a same side of the active layer 23 of the third transistor T3, and the active layer 27 of the seventh transistor T7 is located at a side of the active layer 26 of the sixth transistor T6 away from the active layer 23 of the third transistor T3.

In an exemplary implementation, taking the sub-pixels in the Mth row and the Nth column as an example: in the first direction X, the active layer 24 of the fourth transistor T4 and the active layer 25 of the fifth transistor T5 are located on a side of the active layer 23 of the third transistor T3 away from the sub-pixels in the (N+1)th column, and the active layer 26 of the sixth transistor T6 is located on a side of the active layer 23 of the third transistor T3 away from the sub-pixels in the (N−1)th column; and in the second direction Y, the active layer 24 of the fourth transistor T4 is located on a side of the active layer 23 of the third transistor T3 away from the sub-pixels in the (M−1)th row, the active layer 25 of the fifth transistor T5, the active layer 26 of the sixth transistor T6, and the active layer 27 of the seventh transistor T7 are located on a side of the active layer 23 of the third transistor T3 away from the sub-pixels in the (M+1)th row, and the active layer 27 of the seventh transistor T7 is located on a side of the active layer 26 of the sixth transistor T6 away from the active layer 23 of the third transistor T3.

In an exemplary implementation, the active layer 23 of the third transistor T3 may in a shape of an inverted “(2”, the active layer 24 of the fourth transistor T4 and the active layer 27 of the seventh transistor T7 may in a shape of an “I”, and the active layer 25 of the fifth transistor T5 and the active layer 26 of the sixth transistor T6 may in a shape of an “L”.

In an exemplary implementation, the active layer of each transistor may include a first region, a second region, and a channel region located between the first region and the second region. In an exemplary implementation, a first region 23-1 of the active layer 23 of the third transistor T3 may serve as a second region 24-2 of the active layer 24 of the fourth transistor T4 and a second region 25-2 of the active layer 25 of the fifth transistor T5, a second region 23-2 of the active layer 23 of the third transistor T3 may serve as a first region 26-1 of the active layer 26 of the sixth transistor T6, a second region 26-2 of the active layer 26 of the sixth transistor T6 may serve as a second region 27-2 of the active layer 27 of the seventh transistor T7, and a first region 24-1 of the active layer 24 of the fourth transistor T4, a first region 25-1 of the active layer 25 of the fifth transistor T5, and a first region 27-1 of the active layer 27 of the seventh transistor T7 may be arranged separately.

In an exemplary implementation, an orthographic projection of the active layer 23 of the third transistor T3 on the substrate is at least partially overlapped with an orthographic projection of the shielding block 14 on the substrate. In an exemplary implementation, an orthographic projection of the channel region of the active layer 23 of the third transistor T3 on the substrate is within the range of the orthographic projection of the shielding block 14 on the substrate.

In an exemplary implementation, in each sub-pixel, the first region 25-1 of the active layer 25 of the fifth transistor T5 in the Nth column and the first region 25-1 of the active layer 25 of the fifth transistor T5 in the (N−1)th column are connected to each other, and the first region 25-1 of the active layer 25 of the fifth transistor T5 in the (N+1)th column and the first region 25-1 of the active layer 25 of the fifth transistor T5 in the (N+2)th column are connected to each other. In an exemplary implementation, because a first region of the active layer 25 of the fifth transistor T5 in each sub-pixel is connected to a first power supply line formed subsequently, by forming first regions of the active layer 25 of the fifth transistor T5 of adjacent sub-pixels into an interconnected integral structure, first electrodes of the fifth transistors T5 in the adjacent sub-pixels may be ensured to have a same potential, which is beneficial to improving uniformity of a panel and avoiding display defect of the display substrate, thereby ensuring a display effect of the display substrate.

In an exemplary implementation, the first semiconductor layer in the Nth column and the first semiconductor layer in the (N+1)th column may be mirror symmetrical with respect to the first center line, the first semiconductor layer in the (N+1)th column and the first semiconductor layer in the (N+2)th column may be mirror symmetrical with respect to the second center line, and the first semiconductor layer in the (N+2)th column and the first semiconductor layer in the (N+3)th column may be mirror symmetrical with respect to the third center line.

In an exemplary implementation, the first semiconductor layer may be made of polysilicon (p-Si), i.e., the third transistor T3 to the seventh transistor T7 may be LTPS thin film transistors. In an exemplary implementation, patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a polysilicon thin film. Subsequently, the polysilicon thin film is patterned to form the pattern of the first semiconductor layer.

(104) A pattern of a first conductive layer is formed. In an exemplary implementation, forming the pattern of the first conductive layer may include: sequentially depositing a second insulation thin film and a first conductive thin film on the substrate on which the above-mentioned patterns are formed, patterning the first conductive thin film through a patterning process to form a second insulation layer that covers the pattern of the first semiconductor layer and the pattern of the first conductive layer disposed on the second insulation layer, as shown in FIG. 11a and FIG. 11b, wherein FIG. 11b is a planar schematic view of the first conductive layer in FIG. 11a. In an exemplary implementation, the first conductive layer may be referred to as a first gate metal (GATE1) layer.

In an exemplary implementation, the pattern of the first conductive layer may at least include: a first scan signal line 31, a light emitting control line 32, a first plate 33 of a storage capacitor, and a third scan signal line 34, wherein main portions of the first scan signal line 31, the light emitting control line 32 and the third scan signal line 34 may extend in the first direction X, and in a same sub-pixel, the first scan signal line 31, the light emitting control line 32, the first plate 33 of the storage capacitor and the third scan signal line 34 are arranged in the second direction Y.

In an exemplary implementation, in the second direction Y, the third scan signal line 34 and the light emitting control line 32 are located on both sides of the first plate 33 of the storage capacitor, and the first scan signal line 31 is located at a side of the light emitting control line 32 away from the first plate 33 of the storage capacitor. For example, in the second direction, the first scan signal line 31, the light emitting control line 32, the first plate 33 and the third scan signal line 34 are arranged sequentially.

Taking the sub-pixels in the Mth row and the Nth column as an example, in the second direction Y, the third scan signal line 34 may be located at a side of the first plate 33 of the storage capacitor in the sub-pixel close to the sub-pixels in the (M+1)th row; and the light emitting control line 32 may be located at a side of the first plate 33 of the storage capacitor in the sub-pixel close to the sub-pixels in the (M−1)th row.

In an exemplary implementation, the first plate 33 may be located between the light emitting control line 32 and the third scan signal line 34, the first plate 33 may be in a shape of a rectangle, corners of the rectangle may be chamfered, and there is an overlapping area between an orthographic projection of the first plate 33 on the substrate and an orthographic projection of the active layer of the third transistor T3 on the substrate. In an exemplary embodiment, the first plate 33 may simultaneously serve as a plate of the storage capacitor and the control electrode of the third transistor T3.

In an exemplary implementation, a region where the light emitting control line 32 overlaps the active layer of the fifth transistor T5 serves as the control electrode of the fifth transistor T5, a region where the light emitting control line 32 overlaps the active layer of the sixth transistor T6 serves as the control electrode of the sixth transistor T6, a region where the first scan signal line 31 overlaps the active layer of the seventh transistor T7 serves as the control electrode of the seventh transistor T7, and a region where the third scan signal line 34 overlaps the active layer of the fourth transistor T4 serves as the control electrode of the fourth transistor T4. In an embodiment of the present disclosure, the first scan signal line 31 and the third scan signal line 34 are used as control electrodes of the seventh transistor T7 and the fourth transistor T4, respectively, which, compared with the scheme in which a same scan signal line is used as control electrodes of the fourth transistor T4 and the seventh transistor T7, can reduce a load on the third scan signal line 34 that serves as the control electrode of the fourth transistor T4, and reduce a rise time (Tr) and a fall time (Tf) of a potential change when the fourth transistor T4 is turned off and turned on. Because the fourth transistor T4 controls writing of a potential of the control electrode of the drive transistor T3, reduction in the Tr/Tf of the potential change when the fourth transistor T4 is turned off and turned on can enhance a potential charging rate of the driver transistor T3, thereby further improving display uniformity.

In an exemplary implementation, the first scan signal line 31, the light emitting control line 32 and the third scan signal line 34 may be designed to have an equal width or a non-equal width, which not only can facilitate the layout of the pixel structure, but also can reduce a parasitic capacitance between the signal lines.

In an exemplary implementation, after the pattern of the first conductive layer is formed, the semiconductor layer may be subjected to a conductive treatment by using the first conductive layer as a shield. An area of the semiconductor layer, which is shielded by the first conductive layer, forms channel regions of the third transistor T3 to the seventh transistor T7, and an area of the semiconductor layer, which is not shielded by the first conductive layer, is made to be conductive, that is, the first regions and the second regions of the active layer 23 of the third transistor T3 to the active layer 27 of the seventh transistor T7 are all made to be conductive.

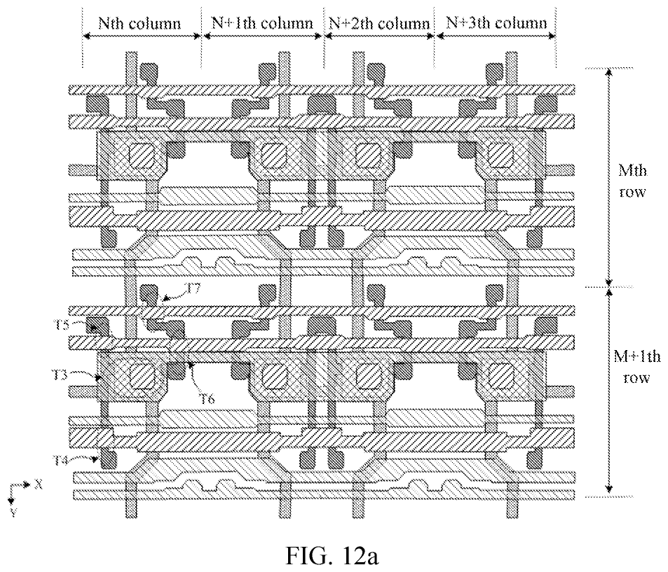

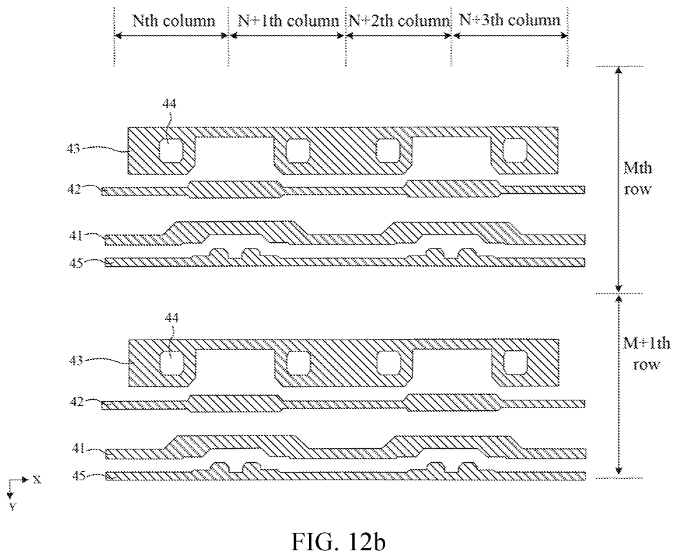

(105) A pattern of a second conductive layer is formed. In an exemplary implementation, forming the pattern of the second conductive layer may include: depositing sequentially a third insulation thin film and a second conductive thin film on the substrate on which the aforementioned patterns are formed, and patterning the second conductive thin film through a patterning process to form a third insulation layer covering the first conductive layer and the pattern of the second conductive layer disposed on the third insulation layer, as shown in FIG. 12a and FIG. 12b, wherein FIG. 12a is a diagram of a planar structure of eight sub-pixels, and FIG. 12b is a planar schematic view of the second conductive layer in FIG. 12a. In an exemplary implementation, the second conductive layer may be referred to as a second gate metal (GATE2) layer.

In an exemplary implementation, the pattern of the second conductive layer at least includes: a first shielding line 41, a second shielding line 42, a second plate 43 of the storage capacitor, and a first initial signal line 45. Main portions of the first shielding line 41, the second shielding line 42 and the first initial signal line 45 may extend in the first direction X. The second plate 43 of the storage capacitor serves as the other plate of the storage capacitor. In the second direction Y, the second shielding line 42 is located between the first shielding line 41 and the second plate 43, and the first shielding line 41 is located between the second shielding line 42 and the first initial signal line 45. For example, in a same sub-pixel, the second plate 43 of the storage capacitor, the second shielding line 42, the first shielding line 41 and the first initial signal line 45 are arranged sequentially in the second direction Y.

In an exemplary implementation, the first shielding line 41 is configured as a shielding layer of the first transistor T1 to shield the channel of the first transistor T1, and the second shielding line 42 is configured as a shielding layer of the second transistor T2 to shield the channel of the second transistor T2, thereby ensuring electrical performances of a first oxide transistor T1 and a second oxide transistor T2.

In an exemplary implementation, a profile of the second plate 43 may be in a shape of a rectangle whose corners may be chamfered, there is an overlapping area between an orthographic projection of the second plate 43 on the substrate and an orthographic projection of the first plate 33 on the substrate, and the first plate 33 and the second plate 43 form the storage capacitor of the pixel drive circuit. The second plate 43 is provided with an opening 44, and the opening 44 may be located in the middle of the second plate 43. The opening 44 may be rectangular and makes the second plate 43 form an annular structure. The opening 44 exposes the third insulation layer covering the first plate 33, and an orthographic projection of the first plate 33 on the substrate contains an orthographic projection of the opening 44 on the substrate. In an exemplary embodiment, the opening 44 is configured to accommodate a ninth via hole subsequently formed, the ninth via hole is located in the opening 44 and exposes the first plate 33, so that a second electrode of the first transistor T1 subsequently formed is connected to the first plate 33.

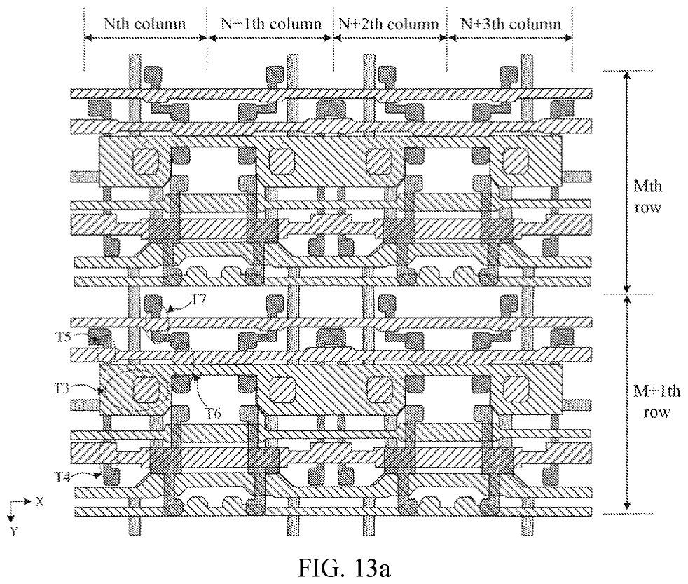

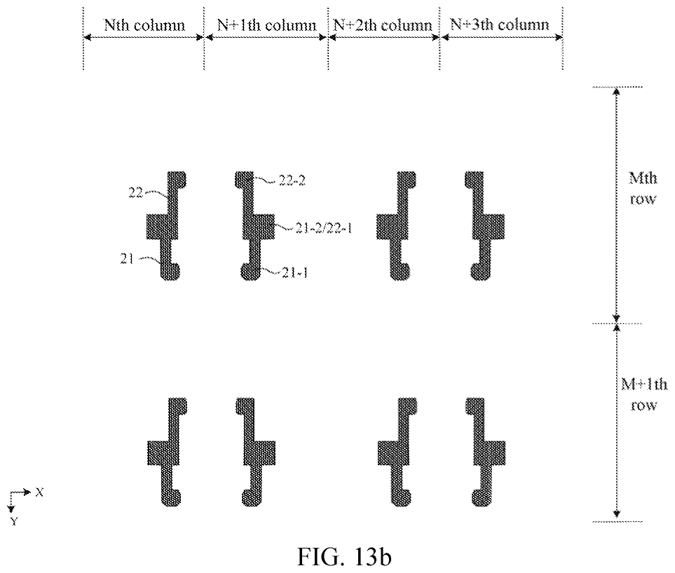

(106) A pattern of a second semiconductor layer is formed. In an exemplary implementation, forming the pattern of the second semiconductor layer may include: depositing sequentially a fourth insulation thin film and a second semiconductor thin film on the substrate on which the aforementioned patterns are formed, and patterning the second semiconductor thin film by a patterning process to form a fourth insulation layer covering the substrate and the pattern of the second semiconductor layer disposed on the fourth insulation layer, as shown in FIG. 13a and FIG. 13b, wherein FIG. 13a is a diagram of a planar structure of eight sub-pixels and FIG. 13b is a planar schematic view of the second semiconductor layer in FIG. 13a.

In an exemplary implementation, the pattern of the second semiconductor layer in each sub-pixel at least includes: the active layer 21 of the first transistor T1 and the active layer 22 of the second transistor T2, and the active layer 21 of the first transistor T1 and the active layer 22 of the second transistor T2 are connected to each other to form an integrated structure.

In an exemplary implementation, the active layer 21 of the first transistor T1 and the active layer 22 of the second transistor T2 may be in a shape of “I”, the second region 21-2 of the active layer 21 of the first transistor T1 may serve as the first region 22-1 of the active layer 22 of the second transistor T2, and the first region 21-1 of the active layer 21 of the first transistor T1 and the second region 22-2 of the second active layer 22 may be separately disposed.

In an exemplary implementation, the second semiconductor layer in the Nth column and the second semiconductor layer in the (N+1)th column may be mirror symmetrical with respect to the first center line, the second semiconductor layer in the (N+1)th column and the second semiconductor layer in the (N+2)th column may be mirror symmetrical with respect to the second center line, and the second semiconductor layer in the (N+2)th column and the second semiconductor layer in the (N+3)th column may be mirror symmetrical with respect to the third center line.

In an exemplary implementation, shapes of the second semiconductor layers in a plurality of sub-pixels may be the same.

In an exemplary implementation, in a plane where the display substrate is located, in the first direction X, the active layer 21 of the first transistor T1 and the active layer 22 of the second transistor T2 are located at a side of the active layer 23 of the third transistor T3 away from the active layer 24 of the fourth transistor T4; and in the second direction Y, the active layer 21 of the first transistor T1 and the active layer 22 of the second transistor T2 are located at a side of the active layer 23 of the third transistor T3 away from the active layer 25 of the fifth transistor T5, and the active layer 21 of the first transistor T1 is located at a side of the active layer 22 of the second transistor T2 away from the active layer 23 of the third transistor T3.

In an exemplary implementation, the second semiconductor layer may be made of an oxide, that is, the first transistor T1 and the second transistor T2 are oxide thin film transistors. In an exemplary implementation, the oxide may be any one or more of Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Oxysulfide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementations, the second semiconductor thin film may be made of indium gallium zinc oxide (IGZO), wherein an electron mobility of indium gallium zinc oxide (IGZO) is higher than an electron mobility of amorphous silicon. Because the leakage current of IGZO TFT is relatively small, both the first transistor T1 and the second transistor T2 are N-type transistors, which can avoid the leakage of electricity of the second node N2 in the light emitting stage.

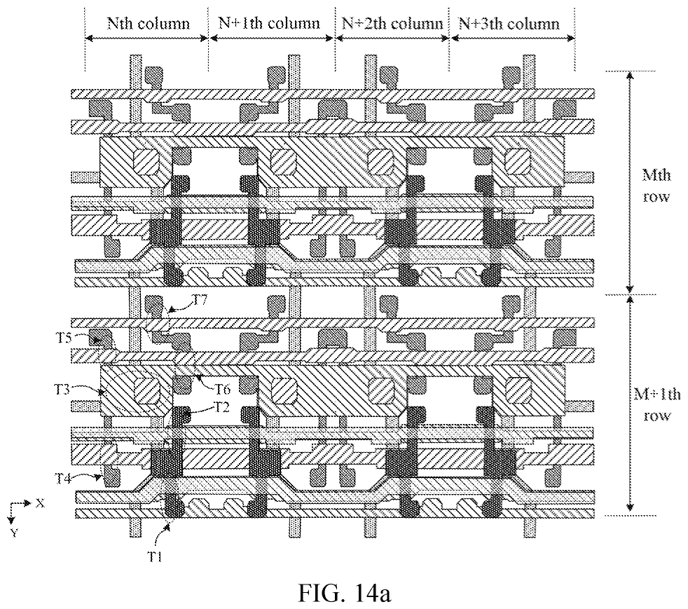

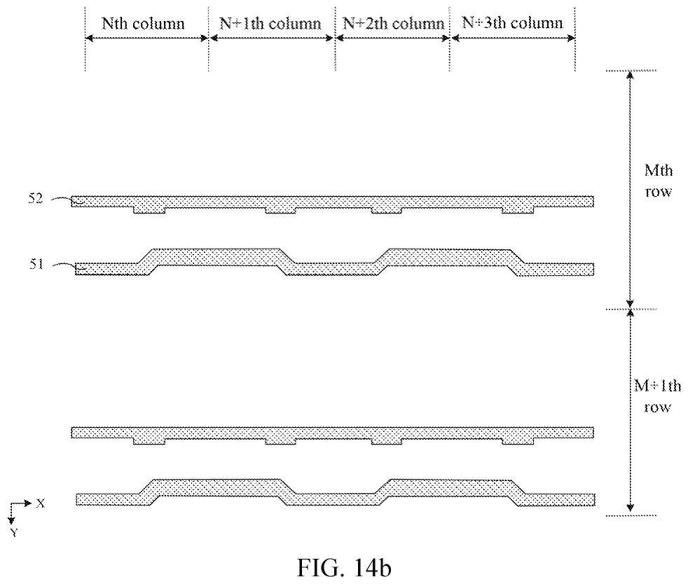

(107) A pattern of a third conductive layer is formed. In an exemplary implementation, forming the pattern of the third conductive layer may include: depositing sequentially a fifth insulation thin film and a third conductive thin film on the substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIG. 14a and FIG. 14b, wherein FIG. 14a is a diagram of a planar structure of eight sub-pixels, and FIG. 14b is a planar schematic view of the third conductive layer in FIG. 14a. In an exemplary implementation, the third conductive layer may be referred to as a third gate metal (GATE3) layer.

In an exemplary implementation, the pattern of the third conductive layer at least includes a second scan signal line 51 and a fourth scan signal line 52, main portions of the second scan signal line 51 and the fourth scan signal line 52 may extend in the first direction X, and the fourth scan signal line 52 and the second scan signal line 51 are sequentially arranged in the second direction Y.

In an exemplary implementation, an area where the second scan signal line 51 overlaps the active layer 21 of the first transistor T1 serves as the control electrode of the first transistor T1, and an area where the fourth scan signal line 52 overlaps the active layer 22 of the second transistor T2 serves as the control electrode of the second transistor T2.

In an exemplary implementation, signals of the first shielding line 41 and the second scan signal line 51 may be the same, i.e. they are connected to a same signal source, so that the first shielding line 41 may serve as a bottom gate electrode (i.e., a bottom control electrode) of the first transistor T1, forming the first transistor T1 of a double gate structure.

In an exemplary implementation, signals of the second shielding line 42 and the fourth scan signal line 52 may be the same, i.e. they are connected to a same signal source, so that the second shielding line 42 may serve as a bottom gate electrode (i.e., a bottom control electrode) of the second transistor T2, forming the second transistor T2 of a double gate structure.

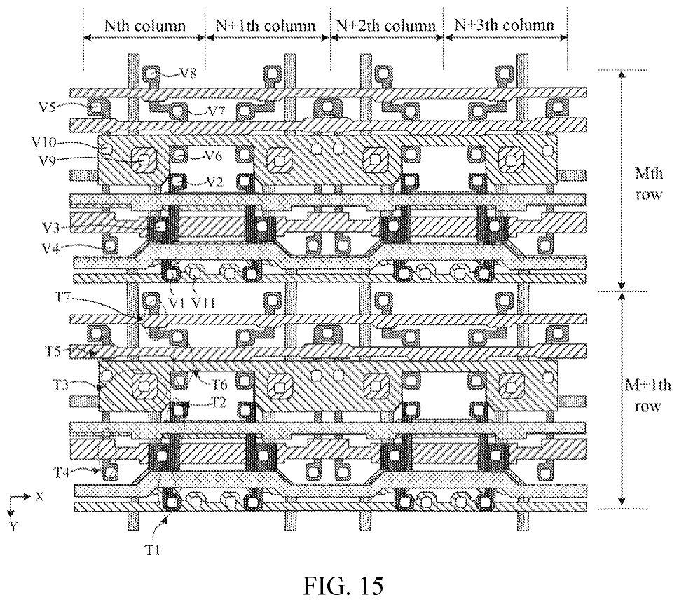

(108) A pattern of a sixth insulation layer is formed. In an exemplary implementation, forming the pattern of the sixth insulation layer may include: depositing a sixth insulation thin film on the substrate on which the aforementioned patterns are formed, and patterning the sixth insulation thin film through a patterning process to form a sixth insulation layer covering the third conductive layer, the sixth insulation layer being provided with a plurality of via holes, as shown in FIG. 15 which is a diagram of a planar structure of eight sub-pixels.

In an exemplary implementation, the plurality of via holes in each sub-pixel at least include: a first via hole V1, a second via hole V2, a third via hole V3, a fourth via hole V4, a fifth via hole V5, a sixth via hole V6, a seventh via hole V7, an eighth via hole V8, a ninth via hole V9, a tenth via hole V10, and an eleventh via hole V11.

In an exemplary implementation, an orthographic projection of the first via hole V1 on the substrate is located within a range of an orthographic projection of the active layer 21 of the first transistor T1 on the substrate, and the sixth insulation layer and the fifth insulation layer in the first via hole V1 are etched away, exposing a surface of a first region 21-1 of the active layer 21 of the first transistor T1. The first via hole V1 is configured so that the first electrode of the first transistor T1 subsequently formed is connected to the active layer 21 of the first transistor T1 through this via hole.

In an exemplary implementation, an orthographic projection of the second via hole V2 on the substrate is located within a range of an orthographic projection of the active layer 22 of the second transistor T2 on the substrate, and the sixth insulation layer and the fifth insulation layer in the second via hole V2 are etched away, exposing a surface of a second region 22-2 of the active layer 22 of the second transistor T2. The second via hole V2 is configured so that the second electrode of the second transistor T2 subsequently formed is connected to the active layer 22 of the second transistor T2 through this via hole.

In an exemplary implementation, an orthographic projection of the third via hole V3 on the substrate is located within a range of an orthographic projection of the active layer 22 of the second transistor T2 on the substrate, and the sixth insulation layer and the fifth insulation layer in the third via hole V3 are etched away, exposing a surface of a first region 22-1 (it is also a second region 21-2 of the active layer 21 of the first transistor T1) of the active layer 22 of the second transistor T2. The third via hole V3 is configured so that the second electrode of the first transistor T1 subsequently formed is connected to the active layer 21 of the first transistor T1 through this via hole, and the first electrode of the second transistor T2 subsequently formed is connected to the active layer 22 of the second transistor T2 through this via hole.

In an exemplary implementation, an orthographic projection of the first via hole V4 on the substrate is located within a range of an orthographic projection of the active layer 24 of the fourth transistor T4 on the substrate, and the sixth insulation layer, the fifth insulation layer, the fourth insulation layer, the third insulation layer and the second insulation layer in the fourth via hole V4 are etched away, exposing the first region 24-1 of the active layer 24 of the fourth transistor T4. The fourth via hole V4 is configured so that the first electrode of the fourth transistor T4 subsequently formed is connected to the active layer 24 of the fourth transistor T4 through this via hole.

In an exemplary implementation, an orthographic projection of the fifth via hole V5 on the substrate is located within a range of an orthographic projection of the active layer 25 of the fifth transistor T5 on the substrate, and the sixth insulation layer, the fifth insulation layer, the fourth insulation layer, the third insulation layer and the second insulation layer in the fifth via hole V5 are etched away, exposing a surface of a first region 25-1 of the active layer 25 of the fifth transistor T5. The fifth via hole V5 is configured so that the first electrode of the fifth transistor T5 subsequently formed is connected to the active layer 25 of the fifth transistor T5 through this via hole.

In an exemplary implementation, an orthographic projection of the sixth via hole V6 on the substrate is located within a range of an orthographic projection of the active layer 26 of the sixth transistor T6 on the substrate, and the sixth insulation layer, the fifth insulation layer, the fourth insulation layer, the third insulation layer and the second insulation layer in the sixth via hole V6 are etched away, exposing a surface of a first region 26-1 (it is also a second region of the active layer 23 of the third transistor T3) of the active layer 26 of the sixth transistor T6. The sixth via hole V6 is configured so that the first electrode of the sixth transistor T6 subsequently formed is connected to the active layer 26 of the sixth transistor T6 through this via hole, and the second electrode of the third transistor T3 subsequently formed is connected to the active layer 23 of the third transistor T3 through this via hole.

In an exemplary implementation, an orthographic projection of the seventh via hole V7 on the substrate is located within a range of an orthographic projection of the active layer 26 of the sixth transistor T6 on the substrate, and the sixth insulation layer, the fifth insulation layer, the fourth insulation layer, the third insulation layer and the second insulation layer in the seventh via hole V7 are etched away, exposing a surface of a second region 26-2 (it is also a second region 27-2 of the active layer 27 of the seventh transistor T7) of the active layer 26 of the sixth transistor T6. The seventh via hole V7 is configured so that the second electrode of the sixth transistor T6 subsequently formed is connected to the active layer 26 of the sixth transistor T6 through this via hole, and the second electrode of the seventh transistor T7 subsequently formed is connected to the active layer 27 of the seventh transistor T7 through this via hole.

In an exemplary implementation, an orthographic projection of the eighth via hole V8 on the substrate is located within a range of an orthographic projection of the active layer 27 of the seventh transistor T7 on the substrate, and the sixth insulation layer, the fifth insulation layer, the fourth insulation layer, the third insulation layer and the second insulation layer in the eighth via hole V8 are etched away, exposing a surface of a first region 27-1 of the active layer 27 of the seventh transistor T7. The eighth via hole V8 is configured so that the first electrode of the seventh transistor T7 subsequently formed is connected to the active layer 27 of the seventh transistor T7 through this via hole.

In an exemplary implementation, an orthographic projection of the ninth via hole V9 on the substrate is located within a range of an orthographic projection of the opening 44 on the substrate, and the sixth insulation layer, the fifth insulation layer, the fourth insulation layer and the third insulation layer in the ninth via hole V9 are etched away, exposing a surface of the first plate 33. The ninth via hole V9 is configured so that the second electrode of the first transistor T1 subsequently formed is connected to the first plate 33 through this via hole.

In an exemplary implementation, the tenth via hole V10 is located within a range of an orthographic projection of the second plate 43 on the substrate, and the sixth insulation layer, the fifth insulation layer and the fourth insulation layer in the tenth via hole V10 are etched away, exposing a surface of the second plate 43. The tenth via hole V10 is configured so that the fifth connection electrode 45 formed subsequently is connected to the second plate 43 through this via hole. In an exemplary embodiment, there may be a plurality of tenth via holes V10 which serve as power supply via holes, and the plurality of tenth via holes V10 may be sequentially arranged in the second direction Y or the first direction X, thereby increasing the reliability of the connection between the first power supply line and the second plate 43.

In an exemplary implementation, an orthographic projection of the eleventh via hole V11 on the substrate is within a range of an orthographic projection of the first initial signal line 45 on the substrate, and the sixth insulation layer, the fifth insulation layer and the fourth insulation layer in the eleventh via hole V11 are etched away, exposing a surface of the first initial signal line 45. The eleventh via hole V11 is configured so that the first electrode of the first transistor T1 subsequently formed is connected to the first initial signal line 45 through this via hole.

(109) A pattern of a fourth conductive layer is formed. In an exemplary embodiment, forming the fourth conductive layer may include: depositing a fourth conductive thin film on the substrate on which the aforementioned patterns are formed, and patterning the fourth conductive thin film by a patterning process to form the fourth conductive layer disposed on the sixth insulation layer, as shown in FIG. 16a and FIG. 16b, wherein FIG. 16a is a diagram of a planar structure of eight sub-pixels, and FIG. 16b is a planar schematic view of the fourth conductive layer in FIG. 16a. In an exemplary implementation, the fourth conductive layer may be referred to as a first source drain metal (SD1) layer.

In an exemplary implementation, the fourth conductive layer at least includes: a first connection electrode 61, a second connection electrode 62, a third connection electrode 63, a fourth connection electrode 64, a fifth connection electrode 65, a sixth connection electrode 66, a second initial signal line 67, a first initial signal connection electrode 68 and a second initial signal connection electrode 69.

In an exemplary implementation, the first connection electrode 61 is in a shape of a bend line whose main portion extends in the second direction Y, a first end of the first connection electrode 61 is connected to the second region 21-2 (it is also the first region 22-1 of the active layer 22 of the second transistor T2) of the active layer 21 of the first transistor T1 through the third via hole V3, and a second end of the first connection electrode 61 is connected to the first plate 33 through the ninth via hole V9, so that the first plate 33, the second electrode of the first transistor T1 and the first electrode of the second transistor T2 have a same potential. In an exemplary embodiment, the first connection electrode 61 may be used as the second electrode of the first transistor T1 and the first electrode of the second transistor T2.

In an exemplary implementation, the second connection electrode 62 may be in a shape of a strip whose main portion extends in the first direction X, and the second connection electrode 62 is connected to the first region 21-1 of the active layer 21 of the first transistor T1 through the first via hole V1 and connected to the first initial signal line 45 in sub-pixels in a row through the eleventh via hole V11 in that sub-pixel row. In an exemplary embodiment, the second connection electrode 62 may serve as the first electrode of the first transistor T1, and the second connection electrode 62 is configured to be connected to the first initial signal line 45 and the active layer 21 of the first transistor T1.

In an exemplary implementation, in each sub-pixel row, the Nth column and the (N+1)th column share a same second connection electrode 62. In an exemplary implementation, because the second connection electrode 62 in each sub-pixel is connected to the first initial signal line 45, by sharing a same second connection electrode 62 between adjacent sub-pixels to form an interconnected integral structure, it may ensure that the second connection electrodes 62 of the adjacent sub-pixels have a same potential, which is beneficial to improving the uniformity of the panel, avoiding display defect of the display substrate, and ensuring the display effect of the display substrate.

In an exemplary implementation, one end of the third connection electrode 63 is connected to the second region 22-2 of the active layer 22 of the second transistor T2 through the second via hole V2, and the other end of the third connection electrode 63 is connected to the second region 23-2 (it is also the first region 26-1 of the active layer 26 of the sixth transistor T6) of the active layer 23 of the third transistor T3 through the sixth via hole V6. In an exemplary embodiment, the third connection electrode 63 may simultaneously serve as the second electrode of the second transistor T2, the second electrode of the third transistor T3, and the first electrode of the sixth transistor T6, so that the second electrode of the second transistor T2, the second electrode of the third transistor T3 and the first electrode of the sixth transistor T6 have a same potential.

In an exemplary implementation, the fourth connection electrode 64 is connected to the first region 24-1 of the active layer 24 of the fourth transistor T4 through the fourth via hole V4. In an exemplary embodiment, the fourth connection electrode 64 may serve as the first electrode of the fourth transistor T4, and is configured to be connected to a data signal line formed subsequently.

In an exemplary implementation, the fifth connection electrode 65 is connected to the first region 25-1 of the active layer 25 of the fifth transistor T5 through the fifth via hole V5, and the fifth connection electrode 65 is connected to the second plate 43 through the tenth via hole V10. In an exemplary embodiment, the fifth connection electrode 65 may serve as the first electrode of the fifth transistor T5, and is configured to be connected to the first power supply line formed subsequently.

In an exemplary implementation, the sixth connection electrode 66 is connected to the second region 26-2 (it is also the second region 27-2 of the active layer 27 of the seventh transistor T7) of the active layer 26 of the sixth transistor T6 through the seventh via hole V7. In an exemplary embodiment, the sixth connection electrode 66 may serve as the second electrode of the sixth transistor T6 and the second electrode of the seventh transistor T7, and the sixth connection electrode 66 is configured to be connected to an anode connection electrode formed subsequently.

In an exemplary implementation, the second initial signal line 67 may be in a shape of a bend line whose main portion extends in the first direction X, and the second initial signal line 67 is connected to the first regions 27-1 of the active layers 27 of a plurality of seventh transistors T7 through a plurality of eighth via holes V8 in a sub-pixel row, to write an initial voltage into the plurality of seventh transistors T7 in the sub-pixel row. In an exemplary embodiment, because the second initial signal line 67 is connected to the first regions 27-1 of the active layers 27 of all seventh transistors T7 in a sub-pixel row, the first electrodes of all seventh transistors T7 in a sub-pixel row may be ensured to have a same potential, which is beneficial to improving uniformity of the panel, avoiding display defect of the display substrate, and ensuring the display effect of the display substrate. In an exemplary embodiment, the second initial signal line 67 may serve as the first electrode of the seventh transistor T7.

In an exemplary implementation, the first initial signal connection electrodes 68 are disposed between adjacent rows of sub-pixels, and are disposed in a structure integrally formed with the second connection electrodes 62 of two adjacent columns. In an exemplary implementation, the first initial signal connection electrode 68 is disposed to be connected to a first initial signal connection line formed subsequently through a via hole. In an exemplary implementation, one or more columns of sub-pixels may be disposed between two adjacent first initial signal connection electrodes 68, for example, four columns of sub-pixels may be disposed between two adjacent first initial signal connection electrodes 68. In an exemplary implementation, the first initial signal connection line is electrically connected to a plurality of first initial signal lines 45 arranged in the second direction through the first initial signal connection electrode 68, to connect the plurality of first initial signal lines 45 arranged in the second direction Y into an integrated structure, to reduce the voltage drop of the first initial signal lines 45, so that the plurality of first initial signal lines 45 have a same potential, which is beneficial to improving the uniformity of the panel, avoiding display defect of the display substrate, and ensuring the display effect of the display substrate.

In an exemplary implementation, the second initial signal connection electrode 69 is disposed in a structure integrally formed with the second initial signal line 67. In an exemplary implementation, the second initial signal connection electrode 69 is disposed between sub-pixels of adjacent columns. In an exemplary implementation, one or more columns of sub-pixels may be disposed between two adjacent second initial signal connection electrodes 69, for example, four columns of sub-pixels are disposed between two adjacent second initial signal connection electrodes 69. In an exemplary implementation, the second initial signal connection electrode 69 is disposed to be connected to a second initial signal connection line formed subsequently through a via hole. In an exemplary implementation, the second initial signal connection line is electrically connected to a plurality of second initial signal lines 67 arranged in the second direction through the second initial signal connection electrode 69, to connect the plurality of second initial signal lines 67 arranged in the second direction Y into an integrated structure, to reduce the voltage drop of the second initial signal lines 67, so that the plurality of second initial signal lines 67 have a same potential, which is beneficial to improving the uniformity of the panel, avoiding display defect of the display substrate, and ensuring the display effect of the display substrate.

In an exemplary implementation, one or more columns of sub-pixels may be disposed between adjacent first initial signal lines 68 and second initial signal connection electrodes 69, for example, two columns of sub-pixels may be disposed between adjacent first initial signal lines 68 and second initial signal connection electrodes 69. In an exemplary implementation, a plurality of pixel column spaces are included between a plurality of pixel columns, and the first initial signal lines 68 and the second initial signal connection electrodes 69 are located in different pixel column spaces.

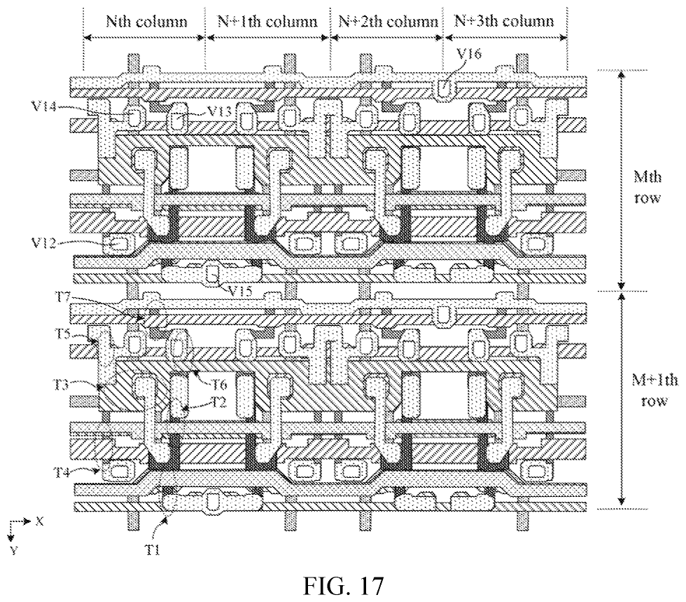

(110) Patterns of a seventh insulation layer and a first planarization layer are formed. In an exemplary embodiment, forming the patterns of the seventh insulation layer and the first planarization layer may include: on the substrate on which the aforementioned patterns are formed, depositing a seventh insulation thin film first, then coating a first planarization thin film, and patterning the first planarization thin film and the seventh insulation thin film by a patterning process to form a seventh insulation layer covering the pattern of the fourth conductive layer and the first planarization layer disposed on the seventh insulation layer, the seventh insulation layer and the first planarization layer being provided with a plurality of via holes, as shown in FIG. 17, which is a diagram of a planar structure of eight sub-pixels.

In an exemplary implementation, a plurality of via holes in each sub-pixel at least include: a twelfth via hole V12, a thirteenth via hole V13, a fourteenth via hole V14, a fifteenth via hole V15 and a sixteenth via hole V16.

In an exemplary implementation, an orthographic projection of the twelfth via hole V12 on the substrate is located within a range of an orthographic projection of a fourth connection electrode 64 on the substrate, and the first planarization layer and the seventh insulation layer in the twelfth via hole V12 are etched away, exposing a surface of the fourth connection electrode 64. The twelfth via hole V12 is configured so that a data signal line formed subsequently is connected to the fourth connection electrode 64 through this via hole.

In an exemplary implementation, an orthographic projection of the thirteenth via hole V13 on the substrate is within a range of an orthographic projection of a sixth connection electrode 66 on the substrate, and the first planarization layer and the seventh insulation layer in the thirteenth via hole V13 are etched away, exposing a surface of the sixth connection electrode 66. The thirteenth via hole V13 is configured so that an anode connection electrode of a light emitting element formed subsequently is connected to the sixth connection electrode 66 through this via hole.

In an exemplary implementation, an orthographic projection of the fourteenth via hole V14 on the substrate is located within a range of an orthographic projection of a fifth connection electrode 65 on the substrate, and the first planarization layer and the seventh insulation layer in the fourteenth via hole V14 are etched away, exposing a surface of the fifth connection electrode 65. The fourteenth via hole V14 is configured so that a first power supply line formed subsequently is connected to the fifth connection electrode 65 through this via hole.

In an exemplary implementation, an orthographic projection of the fifteenth via hole V15 on the substrate is located within a range of an orthographic projection of the first initial signal connection electrode 68 on the substrate, and the first planarization layer and the seventh insulation layer in the fifteenth via hole V15 are etched away, exposing a surface of the first initial signal connection electrode 68. The fifteenth via hole V15 is configured so that a first initial signal connection line formed subsequently is connected to the first initial signal connection electrode 68 through this via hole.

In an exemplary implementation, an orthographic projection of the sixteenth via hole V16 on the substrate is located within a range of an orthographic projection of a second initial signal connection electrode 69 on the substrate, and the first planarization layer and the seventh insulation layer in the sixteenth via hole V16 are etched away, exposing a surface of the second initial signal connection electrode 69. The sixteenth via hole V16 is configured so that a second initial signal connection line formed subsequently is connected to the second initial signal connection electrode 67 through this via hole.

(111) A pattern of a fifth conductive layer is formed. In an exemplary embodiment, forming the fifth conductive layer may include: depositing a fifth conductive thin film on the substrate on which the aforementioned patterns are formed, and patterning the fifth conductive thin film through a patterning process to form the fifth conductive layer disposed on the first planarization layer, as shown in FIG. 18a and FIG. 18b, wherein FIG. 18a is a diagram of a planar structure of eight sub-pixels, and FIG. 18b is a schematic planar view of the fifth conductive layer in FIG. 18a. In an exemplary implementation, the fifth conductive layer may be referred to as a second source drain metal (SD2) layer.

In an exemplary embodiment, the fifth conductive layer at least includes: a data signal line 71, a first power supply line 72, an anode connection electrode 73, a first initial signal connection line 74, and a second initial signal connection line 75.

In an exemplary embodiment, a main portion of the data signal line 71 extends in the second direction Y, and the data signal line 71 is connected to the fourth connection electrode 64 through the twelfth via hole V12. Because the fourth connection electrode 64 is connected to the first region 24-1 of the active layer 24 of the fourth transistor T4 through a via hole, connection between the data signal line 71 and the first electrode of the fourth transistor T4 is achieved, and a data signal is written into the fourth transistor T4.

In an exemplary embodiment, the first power supply line 72 is in a shape of a bend line whose main portion extends in the second direction Y, and the first power supply line 72 is connected to the fifth connection electrode 65 through the fourteenth via hole V14. Because the fifth connection electrode 65 is connected to the second plate 43 through a via hole, connection between the first power supply line 72 and the second plate 43 is achieved, and a power signal is written into the second plate 43. Because the fifth connection electrode 65 is connected to the first region 25-1 of the active layer 25 of the fifth transistor T5 through a via hole, connection between the first power supply line 72 and the first electrode of the fifth transistor T5 is achieved, and a power signal is written into the fifth transistor T5.

In an exemplary embodiment, the anode connection electrode 73 is connected to the sixth connection electrode 66 through the thirteenth via hole V13. Because the sixth connection electrode 66 is connected to the second region 26-2 (it is also the second region 27-2 of the active layer 27 of the seventh transistor T7) of the active layer 26 of the sixth transistor T6 through a via hole, connections between the anode connection electrode 73 and the second electrode of the sixth transistor T6 as well as the second electrode of the seventh transistor T7 are achieved.

In an exemplary embodiment, the main portion of the first initial signal connection line 74 extends in the second direction Y, and the first initial signal connection line 74 is connected to the first initial signal connection electrode 68 through the fifteenth via hole V15. In an exemplary implementation, the first initial signal connection line 74 is disposed between two adjacent columns of sub-pixels. In an exemplary embodiment, one or more columns of sub-pixels may be disposed between two adjacent first initial signal connection lines 74, for example, four columns of sub-pixels may be disposed between two adjacent first initial signal connection lines 74. In an exemplary implementation, the first initial signal connection line 74 is electrically connected to a plurality of first initial signal lines 45 arranged in the second direction through the first initial signal connection electrode 68, to connect the plurality of first initial signal lines 45 arranged in the second direction Y into an integrated structure, to reduce the voltage drop of the first initial signal lines 45, so that the plurality of first initial signal lines 45 have a same potential, which is beneficial to improving the uniformity of the panel, avoiding display defect of the display substrate, and ensuring the display effect of the display substrate.

In an exemplary embodiment, the main portion of the second initial signal connection line 75 extends in the second direction Y, and the second initial signal connection line 75 is connected to the second initial signal connection electrode 69 through the sixteenth via hole V16. In an exemplary implementation, the second initial signal connection line 75 is disposed between two adjacent columns of sub-pixels. In an exemplary embodiment, one or more columns of sub-pixels may be disposed between two adjacent second initial signal connection lines 75, for example, four columns of sub-pixels may be disposed between two adjacent second initial signal connection lines 75. In an exemplary implementation, the second initial signal connection line 75 is electrically connected to a plurality of second initial signal lines 67 arranged in the second direction through the second initial signal connection electrode 69, to connect the plurality of second initial signal lines 67 arranged in the second direction Y into an integrated structure, to reduce the voltage drop of the second initial signal lines 67, so that the plurality of second initial signal lines 67 have a same potential, which is beneficial to improving the uniformity of the panel, avoiding display defect of the display substrate, and ensuring the display effect of the display substrate.

In an exemplary embodiment, one or more columns of sub-pixels may be disposed between adjacent first initial signal connection lines 74 and second initial signal connection lines 75, for example, two columns of sub-pixels may be disposed between adjacent first initial signal connection lines 74 and second initial signal connection lines 75.

In an exemplary implementation, a plurality of pixel column spaces are included between a plurality of pixel columns, and the first initial signal connection line 74 and the second initial signal connection line 75 are located in different pixel column spaces, which fully utilizes the space of the sub-pixel circuit to reduce the voltage drop of the first initial signal line 45 and the second initial signal line 67 without increasing the size of the sub-pixel and changing the line width and spacing of the sub-pixel circuits, and improve the uniformity of the display panel.

In an exemplary implementation, taking 8 sub-pixels (2 pixel rows, 4 pixel columns) as an example, another preparation process for a display substrate may include the following operations.

(201) A substrate is prepared on a glass carrier plate. The preparation method is the same as that in the operation (101) above, and will not be described here.

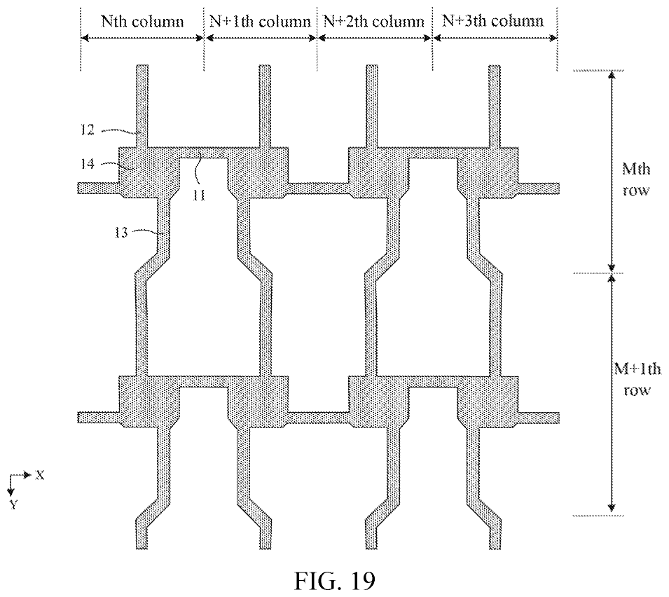

(202) A pattern of a shielding layer is formed. In an exemplary implementation, forming the pattern of the shielding layer may include: depositing a first conductive thin film on the substrate, and patterning the first conductive thin film through a patterning process, to form the pattern of the shielding layer on the substrate, as shown in FIG. 19, which is a diagram of a planar structure of the pattern of the shielding layer in eight sub-pixels.

In an exemplary implementation, the pattern of the shielding layer of each sub-pixel may include a first shielding structure 11, a second shielding structure 12, a third shielding structure 13 and a shielding block 14. A shape of the shielding block 14 may be rectangle, and the corners of the rectangular may be chamfered. The first shielding structure 11 may be in a shape of a strip extending in the first direction X, and the first shielding structure 11 is disposed at a side of the shielding block 14 in the first direction X and connected to the shielding block 14. The second shielding structure 12 may be in a shape of a strip extending in the second direction Y, and the second shielding structure 12 is disposed at a side of the shielding block 14 in an opposite direction of the second direction Y and connected to the shielding block 14. The third shielding structure 13 may be in a shape of a bend line extending in the second direction Y, and the third shielding structure 13 is disposed at a side of the shielding block 14 in the second direction Y and connected to the shielding block 14.

In an exemplary implementation, the first shielding structure 11 of each sub-pixel is connected to the shielding blocks 14 of adjacent sub-pixels in the first direction X such that the shielding layers in a sub-pixel row are connected as a whole to form an interconnected integral structure.

In an exemplary implementation, the second shielding structure 12 of each sub-pixel is connected to the third shielding structures 13 of adjacent sub-pixels in the second direction Y such that the shielding layers in a sub-pixel column are connected as a whole to form an interconnected integral structure.

In an exemplary implementation, the shielding layers in a sub-pixel row and a sub-pixel column are connected as a whole, which may ensure that the shielding layers in the display substrate have a same potential, and this is beneficial to improving uniformity of a panel, avoiding display defect of the display substrate, and ensuring a display effect of the display substrate.

In an exemplary implementation, the shielding layers of the Nth column and the shielding layers of the (N+1)th column may be mirror symmetrical with respect to a first center line, the shielding layers of the (N+1)th column and the shielding layers of the (N+2)th column may be mirror symmetrical with respect to a second center line, the shielding layers of the (N+2)th column and the shielding layers of the (N+3)th column may be mirror symmetrical with respect to a third center line, and the first, second and third center lines may respectively be straight lines extending in the second direction Y between adjacent sub-pixel columns.

In an exemplary implementation, shapes of the shielding layers in a plurality of sub-pixel rows may be the same.

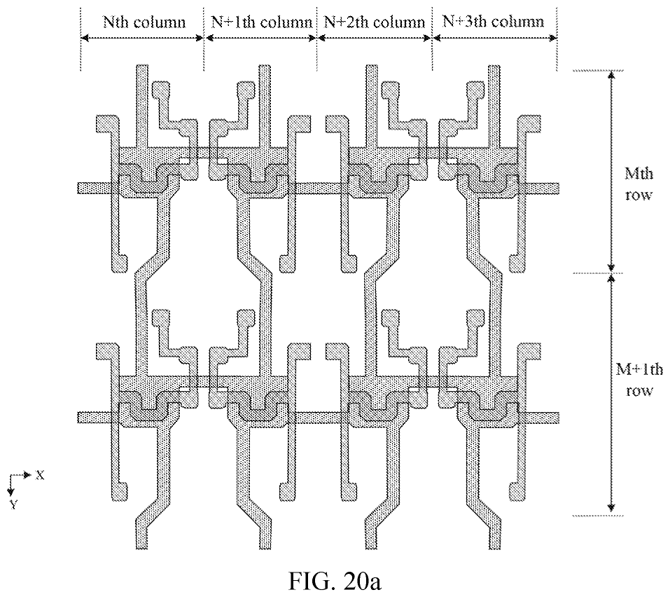

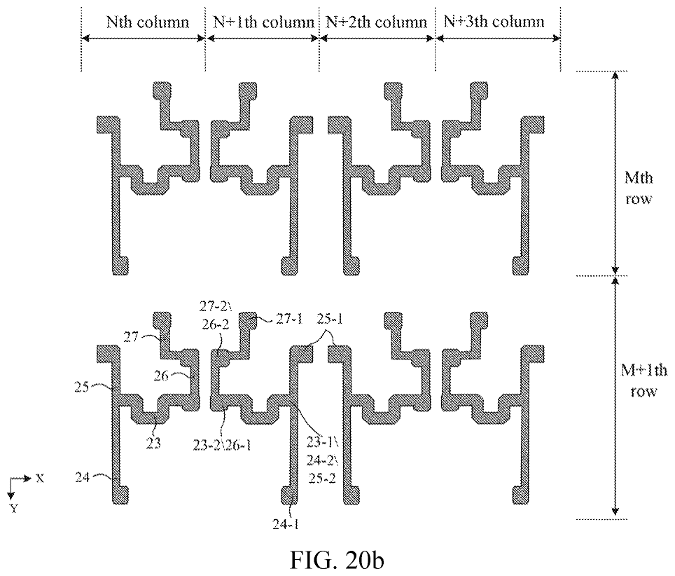

(203) A pattern of a first semiconductor layer is formed. In an exemplary implementation, forming the pattern of the first semiconductor layer may include: depositing sequentially a first insulation thin film and a first semiconductor thin film on the substrate on which the aforementioned pattern is formed, and patterning the first semiconductor thin film through a patterning process to form a first insulation layer covering the pattern of the shielding layer, and the pattern of the first semiconductor layer disposed on the first insulation layer, as shown in FIG. 20, wherein FIG. 20a is a diagram of a planar structure of eight sub-pixels, and FIG. 20b is a planar schematic view of a first semiconductor layer in FIG. 20a.

In an exemplary implementation, the pattern of the first semiconductor layer of each sub-pixel may include the active layer 23 of the third transistor T3 to the active layer 27 of the seventh transistor T7, and the active layer 23 of the third transistor T3 to the active layer 27 of the seventh transistor T7 are connected to each other to form an integrated structure.

In an exemplary implementation, in the first direction X, the active layer 24 of the fourth transistor T4 and the active layer 25 of the fifth transistor T5 are located at a same side of the active layer 23 of the third transistor T3, and the active layer 26 of the sixth transistor T6 is located at the other side of the active layer 23 of the third transistor T3; and in the second direction Y, the active layer 24 of the fourth transistor T4 and the active layer 25 of the fifth transistor T5 are located at both sides of the active layer 23 of the third transistor T3, the active layer 25 of the fifth transistor T5, the active layer 26 of the sixth transistor T6 and the active layer 27 of the seventh transistor T7 are located at a same side of the active layer 23 of the third transistor T3, and the active layer 27 of the seventh transistor T7 is located at a side of the active layer 26 of the sixth transistor T6 away from the active layer 23 of the third transistor T3.

In an exemplary implementation, taking the sub-pixels in the Mth row and the Nth column as an example: in the first direction X, the active layer 24 of the fourth transistor T4 and the active layer 25 of the fifth transistor T5 are located at a side of the active layer 23 of the third transistor T3 away from the sub-pixels in the (N+1)th column, and the active layer 26 of the sixth transistor T6 is located at a side of the active layer 23 of the third transistor T3 away from the sub-pixels in the (N−1)th column; and in the second direction Y, the active layer 24 of the fourth transistor T4 is located at a side of the active layer 23 of the third transistor T3 away from the sub-pixels in the (M−1)th row, the active layer 25 of the fifth transistor T5, the active layer 26 of the sixth transistor T6, and the active layer 27 of the seventh transistor T7 are located at a side of the active layer 23 of the third transistor T3 away from the sub-pixels in the (M+1)th row, and the active layer 27 of the seventh transistor T7 is located at a side of the active layer 26 of the sixth transistor T6 away from the active layer 23 of the third transistor T3.

In an exemplary implementation, the active layer 23 of the third transistor T3 may be in a shape of an inverted “2”, the active layer 24 of the fourth transistor T4 and the active layer 27 of the seventh transistor T7 may be in a shape of an “I”, and the active layer 25 of the fifth transistor T5 and the active layer 26 of the sixth transistor T6 may be in a shape of an “L”.

In an exemplary implementation, the active layer of each transistor may include a first region, a second region, and a channel region located between the first region and the second region. In an exemplary implementation, a first region 23-1 of the active layer 23 of the third transistor T3 may serve as a second region 24-2 of the active layer 24 of the fourth transistor T4 and a second region 25-2 of the active layer 25 of the fifth transistor T5, a second region 23-2 of the active layer 23 of the third transistor T3 may serve as a first region 26-1 of the active layer 26 of the sixth transistor T6, a second region 26-2 of the active layer 26 of the sixth transistor T6 may serve as a second region 27-2 of the active layer 27 of the seventh transistor T7, and a first region 24-1 of the active layer 24 of the fourth transistor T4, a first region 25-1 of the active layer 25 of the fifth transistor T5, and a first region 27-1 of the active layer 27 of the seventh transistor T7 may be arranged separately.

In an exemplary implementation, an orthographic projection of the active layer 23 of the third transistor T3 on the substrate is at least partially overlapped with an orthographic projection of the shielding block 14 on the substrate. In an exemplary implementation, an orthographic projection of the channel region of the active layer 23 of the third transistor T3 on the substrate is within the range of the orthographic projection of the shielding block 14 on the substrate.

In an exemplary implementation, the first semiconductor layer in the Nth column and the first semiconductor layer in the (N+1)th column may be mirror symmetrical with respect to the first center line, the first semiconductor layer in the (N+1)th column and the first semiconductor layer in the (N+2)th column may be mirror symmetrical with respect to the second center line, and the first semiconductor layer in the (N+2)th column and the first semiconductor layer in the (N+3)th column may be mirror symmetrical with respect to the third center line.

In an exemplary implementation, the first semiconductor layer may be made of polysilicon (p-Si), i.e., the third transistor T3 to the seventh transistor T7 may be LTPS thin film transistors. In an exemplary implementation, patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a polysilicon thin film. Subsequently, the polysilicon thin film is patterned to form the pattern of the first semiconductor layer.

(204) A pattern of a first conductive layer is formed. In an exemplary implementation, forming the pattern of the first conductive layer may include: sequentially depositing a second insulation thin film and a first conductive thin film on the substrate on which the above-mentioned patterns are formed, and patterning the first conductive thin film through a patterning process to form a second insulation layer that covers the pattern of the first semiconductor layer and the pattern of the first conductive layer disposed on the second insulation layer, as shown in FIG. 21a and FIG. 21b, wherein FIG. 21b is a planar schematic view of the first conductive layer in FIG. 21a. In an exemplary implementation, the first conductive layer may be referred to as a first gate metal (GATE1) layer.

In an exemplary implementation, the pattern of the first conductive layer may at least include: a first scan signal line 31, a light emitting control line 32, a first plate 33 of a storage capacitor, and a third scan signal line 34, wherein main portions of the first scan signal line 31, the light emitting control line 32 and the third scan signal line 34 may extend in the first direction X, and in a same sub-pixel, the first scan signal line 31, the light emitting control line 32, the first plate 33 of the storage capacitor and the third scan signal line 34 are arranged in the second direction Y.

In an exemplary implementation, in the second direction Y, the third scan signal line 34 and the light emitting control line 32 are located at both sides of the first plate 33 of the storage capacitor, and the first scan signal line 31 is located at a side of the light emitting control line 32 away from the first plate 33 of the storage capacitor. For example, in the second direction, the first scan signal line 31, the light emitting control line 32, the first plate 33 and the third scan signal line 34 are arranged sequentially.

Taking the sub-pixels in the Mth row and the Nth column as an example, in the second direction Y, the third scan signal line 34 may be located at a side of the first plate 33 of the storage capacitor in the sub-pixel close to the sub-pixels in the (M+1)th row; and the light emitting control line 32 may be located at a side of the first plate 33 of the storage capacitor in the sub-pixel close to the sub-pixels in the (M−1)th row.

In an exemplary implementation, the first plate 33 may be located between the light emitting control line 32 and the third scan signal line 34, the first plate 33 may be in a shape of a rectangle, corners of the rectangle may be chamfered, and there is an overlapping area between an orthographic projection of the first plate 33 on the substrate and an orthographic projection of the active layer of the third transistor T3 on the substrate. In an exemplary embodiment, the first plate 33 may simultaneously serve as a plate of the storage capacitor and the control electrode of the third transistor T3.

In an exemplary implementation, a region where the light emitting control line 32 overlaps the active layer of the fifth transistor T5 serves as the control electrode of the fifth transistor T5, a region where the light emitting control line 32 overlaps the active layer of the sixth transistor T6 serves as the control electrode of the sixth transistor T6, a region where the first scan signal line 31 overlaps the active layer of the seventh transistor T7 serves as the control electrode of the seventh transistor T7, and a region where the third scan signal line 34 overlaps the active layer of the fourth transistor T4 serves as the control electrode of the fourth transistor T4. In an embodiment of the present disclosure, the first scan signal line 31 and the third scan signal line 34 are used as control electrodes of the seventh transistor T7 and the fourth transistor T4, respectively, which, compared with the scheme in which a same scan signal line is used as control electrodes of the fourth transistor T4 and the seventh transistor T7, can reduce a load on the third scan signal line 34 that serves as the control electrode of the fourth transistor T4, and reduce a rise time (Tr) and a fall time (Tf) of a potential change when the fourth transistor T4 is turned off and turned on. Because the fourth transistor T4 controls writing of a potential of the control electrode of the drive transistor T3, reduction in the Tr/Tf of the potential change when the fourth transistor T4 is turned off and turned on can enhance a potential charging rate of the driver transistor T3, thereby further improving display uniformity.

In an exemplary implementation, the first scan signal line 31, the light emitting control line 32 and, the third scan signal line 34 may be designed to have an equal width or a non-equal width, which not only can facilitate the layout of the pixel structure, but also can reduce a parasitic capacitance between the signal lines.

In an exemplary implementation, after the pattern of the first conductive layer is formed, the semiconductor layer may be subjected to a conductive treatment by using the first conductive layer as a shield. An area of the semiconductor layer, which is shielded by the first conductive layer, forms channel regions of the third transistor T3 to the seventh transistor T7, and an area of the semiconductor layer, which is not shielded by the first conductive layer, is made to be conductive, that is, the first regions and the second regions of the active layer 23 of the third transistor T3 to the active layer 27 of the seventh transistor T7 are all made to be conductive.

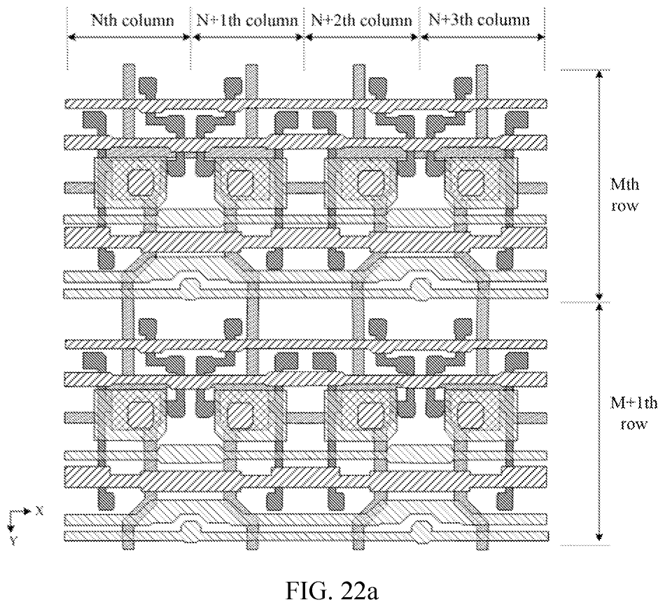

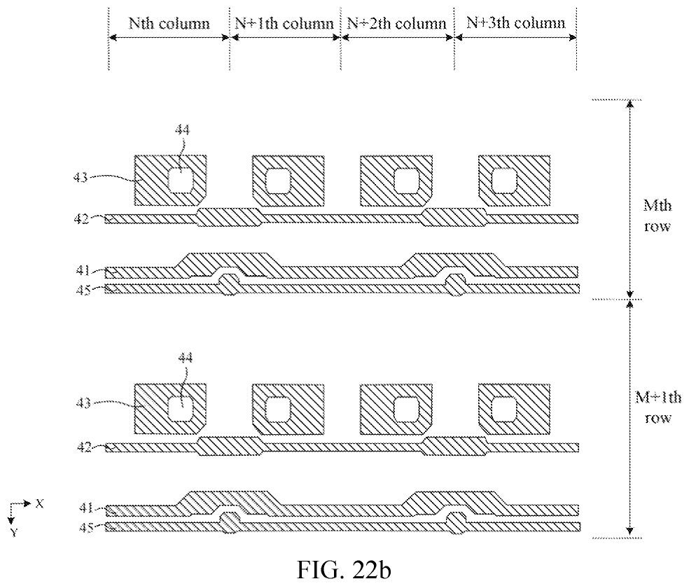

(205) A pattern of a second conductive layer is formed. In an exemplary implementation, forming the pattern of the second conductive layer may include: depositing sequentially a third insulation thin film and a second conductive thin film on the substrate on which the aforementioned patterns are formed, and patterning the second conductive thin film through a patterning process to form a third insulation layer covering the first conductive layer and the pattern of the second conductive layer disposed on the third insulation layer, as shown in FIG. 22a and FIG. 22b, wherein FIG. 22a is a diagram of a planar structure of eight sub-pixels, and FIG. 22b is a planar schematic view of the second conductive layer in FIG. 22a. In an exemplary implementation, the second conductive layer may be referred to as a second gate metal (GATE2) layer.

In an exemplary implementation, the pattern of the second conductive layer at least includes: a first shielding line 41, a second shielding line 42, a second plate 43 of the storage capacitor, and a first initial signal line 45. Main portions of the first shielding line 41, the second shielding line 42 and the first initial signal line 45 may extend in the first direction X. The second plate 43 of the storage capacitor serves as the other plate of the storage capacitor. In the second direction Y, the second shielding line 42 is located between the first shielding line 41 and the second plate 43, and the first shielding line 41 is located between the second shielding line 42 and the first initial signal line 45. For example, in a same sub-pixel, the second plate 43 of the storage capacitor, the second shielding line 42, the first shielding line 41 and the first initial signal line 45 are arranged sequentially in the second direction Y.

In an exemplary implementation, the first shielding line 41 is configured as a shielding layer of the first transistor T1 to shield the channel of the first transistor T1, and the second shielding line 42 is configured as a shielding layer of the second transistor T2 to shield the channel of the second transistor T2, thereby ensuring electrical performances of a first oxide transistor T1 and a second oxide transistor T2.

In an exemplary implementation, a profile of the second plate 43 may be in a shape of a rectangle whose corners may be chamfered, there is an overlapping area between an orthographic projection of the second plate 43 on the substrate and an orthographic projection of the first plate 33 on the substrate, and the first plate 33 and the second plate 43 form the storage capacitor of the pixel drive circuit. The second plate 43 is provided with an opening 44, and the opening 44 may be located in the middle of the second plate 43. The opening 44 may be rectangular and makes the second plate 43 form an annular structure. The opening 44 exposes the third insulation layer covering the first plate 33, and an orthographic projection of the first plate 33 on the substrate contains an orthographic projection of the opening 44 on the substrate. In an exemplary embodiment, the opening 44 is configured to accommodate a ninth via hole subsequently formed, the ninth via hole is located in the opening 44 and exposes the first plate 33, so that a second electrode of the first transistor T1 subsequently formed is connected to the first plate 33.

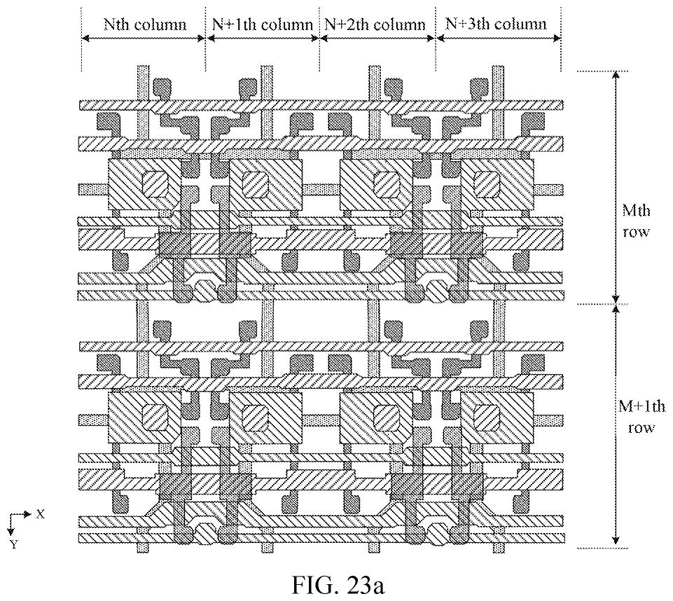

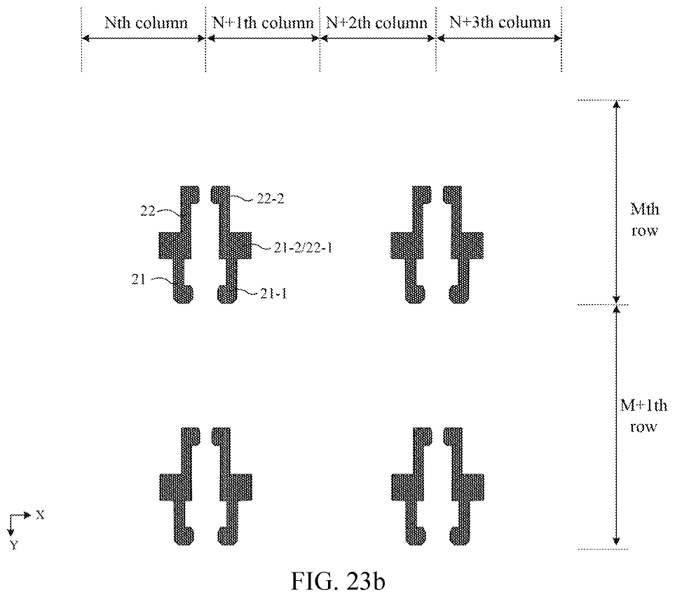

(206) A pattern of a second semiconductor layer is formed. In an exemplary implementation, forming the pattern of the second semiconductor layer may include: depositing sequentially a fourth insulation thin film and a second semiconductor thin film on the substrate on which the aforementioned patterns are formed, and patterning the second semiconductor thin film by a patterning process to form a fourth insulation layer covering the substrate and the pattern of the second semiconductor layer disposed on the fourth insulation layer, as shown in FIG. 23a and FIG. 23b, wherein FIG. 23a is a diagram of a planar structure of eight sub-pixels and FIG. 23b is a planar schematic view of the second semiconductor layer in FIG. 23a.

In an exemplary implementation, the pattern of the second semiconductor layer in each sub-pixel at least includes: the active layer 21 of the first transistor T1 and the active layer 22 of the second transistor T2, and the active layer 21 of the first transistor T1 and the active layer 22 of the second transistor T2 are connected to each other to form an integrated structure.

In an exemplary implementation, the active layer 21 of the first transistor T1 and the active layer 22 of the second transistor T2 may be in a shape of “I”, the second region 21-2 of the active layer 21 of the first transistor T1 may serve as the first region 22-1 of the active layer 22 of the second transistor T2, and the first region 21-1 of the active layer 21 of the first transistor T1 and the second region 22-2 of the second active layer 22 may be separately disposed.

In an exemplary implementation, the second semiconductor layer in the Nth column and the second semiconductor layer in the (N+1)th column may be mirror symmetrical with respect to the first center line, the second semiconductor layer in the (N+1)th column and the second semiconductor layer in the (N+2)th column may be mirror symmetrical with respect to the second center line, and the second semiconductor layer in the (N+2)th column and the second semiconductor layer in the (N+3)th column may be mirror symmetrical with respect to the third center line.

In an exemplary implementation, shapes of the second semiconductor layers in a plurality of sub-pixels row may be the same.

In an exemplary implementation, in a plane where the display substrate is located, in the first direction X, the active layer 21 of the first transistor T1 and the active layer 22 of the second transistor T2 are located at a side of the active layer 23 of the third transistor T3 away from the active layer 24 of the fourth transistor T4; and in the second direction Y, the active layer 21 of the first transistor T1 and the active layer 22 of the second transistor T2 are located at a side of the active layer 23 of the third transistor T3 away from the active layer 25 of the fifth transistor T5, and the active layer 21 of the first transistor T1 is located at a side of the active layer 22 of the second transistor T2 away from the active layer 23 of the third transistor T3.

In an exemplary implementation, the second semiconductor layer may be made of an oxide, that is, the first transistor T1 and the second transistor T2 are oxide thin film transistors. In an exemplary implementation, the oxide may be any one or more of Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Oxysulfide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementations, the second semiconductor thin film may be made of indium gallium zinc oxide (IGZO), wherein an electron mobility of indium gallium zinc oxide (IGZO) is higher than an electron mobility of amorphous silicon. Because the leakage current of IGZO TFT is relatively small, both the first transistor T1 and the second transistor T2 are N-type transistors, which can avoid the leakage of electricity of the second node N2 in the light emitting stage.

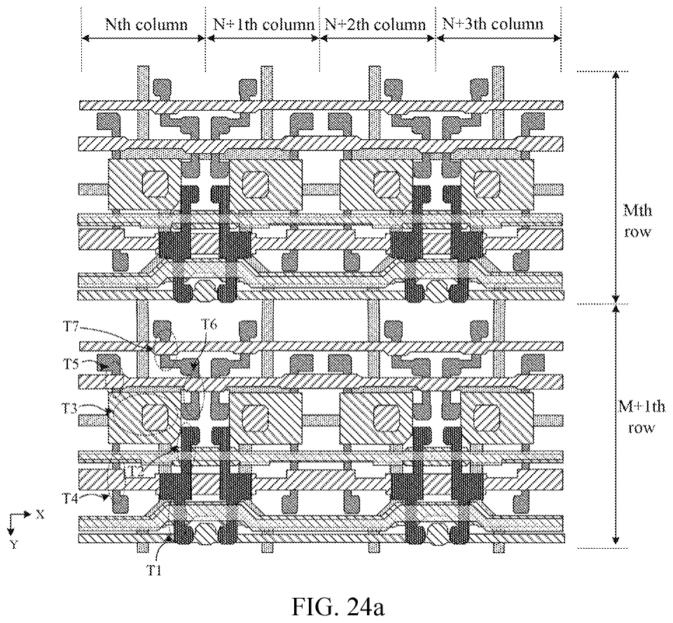

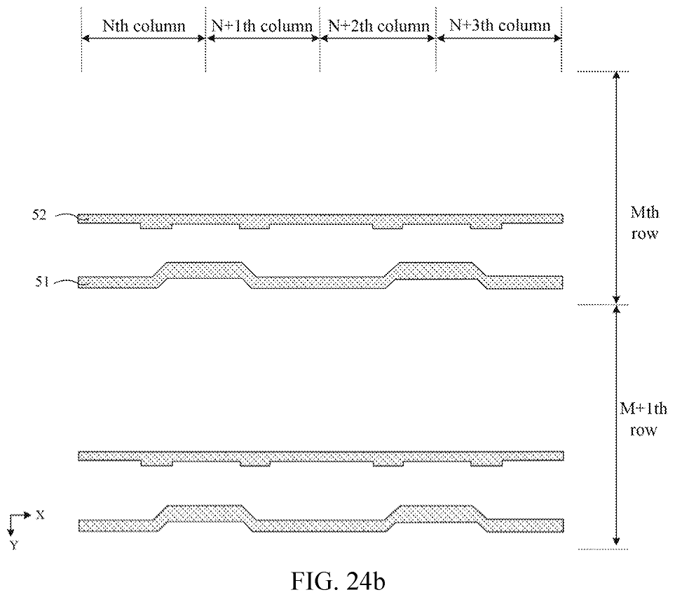

(207) A pattern of a third conductive layer is formed. In an exemplary implementation, forming the pattern of the third conductive layer may include: depositing sequentially a fifth insulation thin film and a third conductive thin film on the substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIG. 24a and FIG. 24b, wherein FIG. 24a is a diagram of a planar structure of eight sub-pixels, and FIG. 24b is a planar schematic view of the third conductive layer in FIG. 24a. In an exemplary implementation, the third conductive layer may be referred to as a third gate metal (GATE3) layer.

In an exemplary implementation, the pattern of the third conductive layer at least includes a second scan signal line 51 and a fourth scan signal line 52, main portions of the second scan signal line 51 and the fourth scan signal line 52 may extend in the first direction X, and the second scan signal line 51, a transfer connection electrode 53 and the fourth scan signal line 52 are sequentially arranged in the second direction Y.

In an exemplary implementation, an area where the second scan signal line 51 overlaps the active layer 21 of the first transistor T1 serves as the control electrode of the first transistor T1, and an area where the fourth scan signal line 52 overlaps the active layer 22 of the second transistor T2 serves as the control electrode of the second transistor T2.

In an exemplary implementation, signals of the first shielding line 41 and the second scan signal line 51 may be the same, i.e. they are connected to a same signal source, so that the first shielding line 41 may serve as a bottom gate electrode (i.e., a bottom control electrode) of the first transistor T1, forming the first transistor T1 of a double gate structure.

In an exemplary implementation, signals of the second shielding line 42 and the fourth scan signal line 52 may be the same, i.e. they are connected to a same signal source, so that the second shielding line 42 may serve as a bottom gate electrode (i.e., a bottom control electrode) of the second transistor T2, forming the second transistor T2 of a double gate structure.

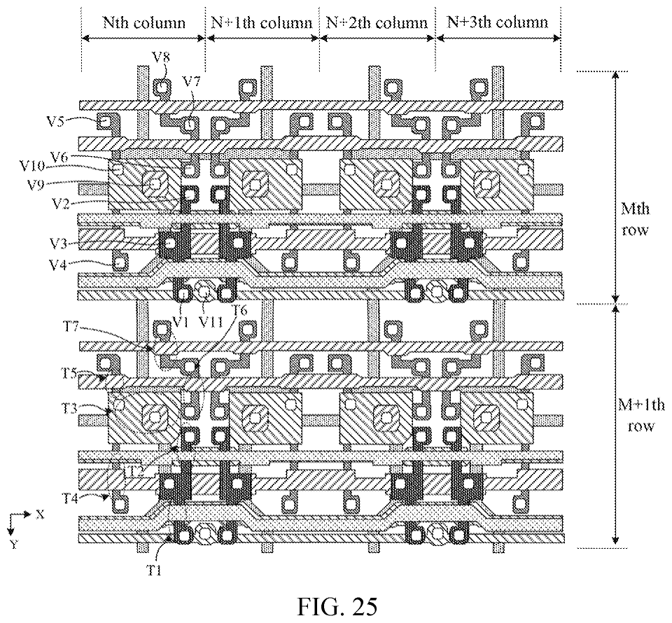

(208) A pattern of a sixth insulation layer is formed. In an exemplary implementation, forming the pattern of the sixth insulation layer may include: depositing a sixth insulation thin film on the substrate on which the aforementioned patterns are formed, and patterning the sixth insulation thin film through a patterning process to form a sixth insulation layer covering the third conductive layer, the sixth insulation layer being provided with a plurality of via holes, as shown in FIG. 25 which is a diagram of a planar structure of eight sub-pixels.

In an exemplary implementation, the plurality of via holes in each sub-pixel at least include: a first via hole V1, a second via hole V2, a third via hole V3, a fourth via hole V4, a fifth via hole V5, a sixth via hole V6, a seventh via hole V7, an eighth via hole V8, a ninth via hole V9, a tenth via hole V10, and an eleventh via hole V11.

In an exemplary implementation, an orthographic projection of the first via hole V1 on the substrate is located within a range of an orthographic projection of the active layer 21 of the first transistor T1 on the substrate, and the sixth insulation layer and the fifth insulation layer in the first via hole V1 are etched away, exposing a surface of a first region 21-1 of the active layer 21 of the first transistor T1. The first via hole V1 is configured so that the first electrode of the first transistor T1 subsequently formed is connected to the active layer 21 of the first transistor T1 through this via hole.

In an exemplary implementation, an orthographic projection of the second via hole V2 on the substrate is located within a range of an orthographic projection of the active layer 22 of the second transistor T2 on the substrate, and the sixth insulation layer and the fifth insulation layer in the second via hole V2 are etched away, exposing a surface of a second region 22-2 of the active layer 22 of the second transistor T2. The second via hole V2 is configured so that the second electrode of the second transistor T2 subsequently formed is connected to the active layer 22 of the second transistor T2 through this via hole.

In an exemplary implementation, an orthographic projection of the third via hole V3 on the substrate is located within a range of an orthographic projection of the active layer 22 of the second transistor T2 on the substrate, and the sixth insulation layer and the fifth insulation layer in the third via hole V3 are etched away, exposing a surface of a first region 22-1 (it is also a second region 21-2 of the active layer 21 of the first transistor T1) of the active layer 22 of the second transistor T2. The third via hole V3 is configured so that the second electrode of the first transistor T1 subsequently formed is connected to the active layer 21 of the first transistor T1 through this via hole, and the first electrode of the second transistor T2 subsequently formed is connected to the active layer 22 of the second transistor T2 through this via hole.

In an exemplary implementation, an orthographic projection of the fourth via hole V4 on the substrate is located within a range of an orthographic projection of the active layer 24 of the fourth transistor T4 on the substrate, and the sixth insulation layer, the fifth insulation layer, the fourth insulation layer, the third insulation layer and the second insulation layer in the fourth via hole V4 are etched away, exposing the first region 24-1 of the active layer 24 of the fourth transistor T4. The fourth via hole V4 is configured so that the first electrode of the fourth transistor T4 subsequently formed is connected to the active layer 24 of the fourth transistor T4 through this via hole.

In an exemplary implementation, an orthographic projection of the fifth via hole V5 on the substrate is located within a range of an orthographic projection of the active layer 25 of the fifth transistor T5 on the substrate, and the sixth insulation layer, the fifth insulation layer, the fourth insulation layer, the third insulation layer and the second insulation layer in the fifth via hole V5 are etched away, exposing a surface of a first region 25-1 of the active layer 25 of the fifth transistor T5. The fifth via hole V5 is configured so that the first electrode of the fifth transistor T5 subsequently formed is connected to the active layer 25 of the fifth transistor T5 through this via hole.

In an exemplary implementation, an orthographic projection of the sixth via hole V6 on the substrate is located within a range of an orthographic projection of the active layer 26 of the sixth transistor T6 on the substrate, and the sixth insulation layer, the fifth insulation layer, the fourth insulation layer, the third insulation layer and the second insulation layer in the sixth via hole V6 are etched away, exposing a surface of a first region 26-1 (it is also a second region of the active layer 23 of the third transistor T3) of the active layer 26 of the sixth transistor T6. The sixth via hole V6 is configured so that the first electrode of the sixth transistor T6 subsequently formed is connected to the active layer 25 of the sixth transistor T6 through this via hole, and the second electrode of the third transistor T3 subsequently formed is connected to the active layer 23 of the third transistor T3 through this via hole.

In an exemplary implementation, an orthographic projection of the seventh via hole V7 on the substrate is located within a range of an orthographic projection of the active layer 26 of the sixth transistor T6 on the substrate, and the sixth insulation layer, the fifth insulation layer, the fourth insulation layer, the third insulation layer and the second insulation layer in the seventh via hole V7 are etched away, exposing a surface of a second region 26-2 (it is also a second region 27-2 of the active layer 27 of the seventh transistor T7) of the active layer 26 of the sixth transistor T6. The seventh via hole V7 is configured so that the second electrode of the sixth transistor T6 subsequently formed is connected to the active layer 26 of the sixth transistor T6 through this via hole, and the second electrode of the seventh transistor T7 subsequently formed is connected to the active layer 27 of the seventh transistor T7 through this via hole.

In an exemplary implementation, an orthographic projection of the eighth via hole V8 on the substrate is located within a range of an orthographic projection of the active layer 27 of the seventh transistor T7 on the substrate, and the sixth insulation layer, the fifth insulation layer, the fourth insulation layer, the third insulation layer and the second insulation layer in the eighth via hole V8 are etched away, exposing a surface of a first region 27-1 of the active layer 27 of the seventh transistor T7. The eighth via hole V8 is configured so that the first electrode of the seventh transistor T7 subsequently formed is connected to the active layer 27 of the seventh transistor T7 through this via hole.

In an exemplary implementation, an orthographic projection of the ninth via hole V9 on the substrate is located within a range of an orthographic projection of the opening 44 on the substrate, and the sixth insulation layer, the fifth insulation layer, the fourth insulation layer and the third insulation layer in the ninth via hole V9 are etched away, exposing a surface of the first plate 33. The ninth via hole V9 is configured so that the second electrode of the first transistor T1 subsequently formed is connected to the first plate 33 through this via hole.

In an exemplary implementation, the tenth via hole V10 is located within a range of an orthographic projection of the second plate 43 on the substrate, and the sixth insulation layer, the fifth insulation layer and the fourth insulation layer in the tenth via hole V10 are etched away, exposing a surface of the second plate 43. The tenth via hole V10 is configured so that the fifth connection electrode 45 formed subsequently is connected to the second plate 43 through this via hole. In an exemplary embodiment, there may be a plurality of tenth via holes V10 which serve as power supply via holes, and the plurality of tenth via holes V10 may be sequentially arranged in the second direction Y or the first direction X, thereby increasing the reliability of the connection between the first power supply line and the second plate 43.

In an exemplary implementation, an orthographic projection of the eleventh via hole V11 on the substrate is within a range of an orthographic projection of the first initial signal line 45 on the substrate, and the sixth insulation layer, the fifth insulation layer and the fourth insulation layer in the eleventh via hole V11 are etched away, exposing a surface of the first initial signal line 45. The eleventh via hole V11 is configured so that the first electrode of the first transistor T1 subsequently formed is connected to the first initial signal line 45 through this via hole.

(209) A pattern of a fourth conductive layer is formed. In an exemplary embodiment, forming the fourth conductive layer may include: depositing a fourth conductive thin film on the substrate on which the aforementioned patterns are formed, and patterning the fourth conductive thin film by a patterning process to form the fourth conductive layer disposed on the sixth insulation layer, as shown in FIG. 26a and FIG. 26b, wherein FIG. 26a is a diagram of a planar structure of eight sub-pixels, and FIG. 26b is a planar schematic view of the fourth conductive layer in FIG. 26a. In an exemplary implementation, the fourth conductive layer may be referred to as a first source drain metal (SD1) layer.

In an exemplary implementation, the fourth conductive layer at least includes: a first connection electrode 61, a second connection electrode 62, a third connection electrode 63, a fourth connection electrode 64, a fifth connection electrode 65, a sixth connection electrode 66, a second initial signal line 67, a first initial signal connection electrode 68 and a second initial signal connection electrode 69.

In an exemplary implementation, the first connection electrode 61 is in a shape of a bend line whose main portion extends in the second direction Y, a first end of the first connection electrode 61 is connected to the second region 21-2 (it is also the first region 22-1 of the active layer 22 of the second transistor T2) of the active layer 21 of the first transistor T1 through the third via hole V3, and a second end of the first connection electrode 61 is connected to the first plate 33 through the ninth via hole V9, so that the first plate 33, the second electrode of the first transistor T1 and the first electrode of the second transistor T2 have a same potential. In an exemplary embodiment, the first connection electrode 61 may be used as the second electrode of the first transistor T1 and the first electrode of the second transistor T2.

In an exemplary implementation, the second connection electrode 62 may be in a shape of a strip or a bend line whose main portion extends in the first direction X, and the second connection electrode 62 is connected to the first region 21-1 of the active layer 21 of the first transistor T1 through the first via hole V1 and connected to the first initial signal line 45 in sub-pixels in a row through the eleventh via hole V11 in that sub-pixel row. In an exemplary embodiment, the second connection electrode 62 may serve as the first electrode of the first transistor T1, and the second connection electrode 62 is configured to be connected to the first initial signal line 45 and the active layer 21 of the first transistor T1.

In an exemplary implementation, in each sub-pixel row, the Nth column and the (N+1)th column share a same second connection electrode 62. In an exemplary implementation, because the second connection electrode 62 in each sub-pixel is connected to the first initial signal line 45, by sharing a same second connection electrode 62 between adjacent sub-pixels to form an interconnected integral structure, it may be ensured that the first initial signal lines 45 of the adjacent sub-pixels have a same potential, which is beneficial to improving the uniformity of the panel, avoiding display defect of the display substrate, and ensuring the display effect of the display substrate.

In an exemplary implementation, one end of the third connection electrode 63 is connected to the second region 22-2 of the active layer 22 of the second transistor T2 through the second via hole V2, and the other end of the third connection electrode 63 is connected to the second region 23-2 (it is also the first region 26-1 of the active layer 26 of the sixth transistor T6) of the active layer 23 of the third transistor T3 through the sixth via hole V6. In an exemplary embodiment, the third connection electrode 63 may simultaneously serve as the second electrode of the second transistor T2, the second electrode of the third transistor T3, and the first electrode of the sixth transistor T6, so that the second electrode of the second transistor T2, the second electrode of the third transistor T3 and the first electrode of the sixth transistor T6 have a same potential.

In an exemplary implementation, the fourth connection electrode 64 is connected to the first region 24-1 of the active layer 24 of the fourth transistor T4 through the fourth via hole V4. In an exemplary embodiment, the fourth connection electrode 64 may serve as the first electrode of the fourth transistor T4, and is configured to be connected to a data signal line formed subsequently.

In an exemplary implementation, the fifth connection electrode 65 is connected to the first region 25-1 of the active layer 25 of the fifth transistor T5 through the fifth via hole V5, and the fifth connection electrode 65 is connected to the second plate 43 through the tenth via hole V10. In an exemplary embodiment, the fifth connection electrode 65 may serve as the first electrode of the fifth transistor T5, and is configured to be connected to the first power supply line formed subsequently.

In an exemplary implementation, the sixth connection electrode 66 is connected to the second region 26-2 (it is also the second region 27-2 of the active layer 27 of the seventh transistor T7) of the active layer 26 of the sixth transistor T6 through the seventh via hole V7. In an exemplary embodiment, the sixth connection electrode 66 may serve as the second electrode of the sixth transistor T6 and the second electrode of the seventh transistor T7, and the sixth connection electrode 66 is configured to be connected to an anode connection electrode formed subsequently.

In an exemplary implementation, the second initial signal line 67 may be in a shape of a bend line whose main portion extends in the first direction X, and the second initial signal line 67 is connected to the first regions 27-1 of the active layers 27 of the seventh transistors T7 in a sub-pixel row through the eighth via holes V8 in the sub-pixel row, to write an initial voltage into the seventh transistors T7 in the sub-pixel row. In an exemplary embodiment, the second initial signal line 67 may serve as the first electrode of the seventh transistor T7.

In an exemplary implementation, the main portion of the first initial signal connection electrode 68 may be in a shape of a strip or a bend line extending in the first direction X, one end of the first initial signal connection electrode 68 may be provided with an electrode connection block 681, and the other end of the first initial signal connection electrode 68 may be connected to the second connection electrode 62, and the first initial signal connection electrode 68 may be disposed in a structure integrally formed with the second connection electrode 62. In an exemplary implementation, the electrode connection block 681 is disposed to be connected to a first initial signal connection line formed subsequently through a via hole. In an exemplary implementation, one or more columns of sub-pixels may be disposed between two adjacent first initial signal connection electrodes 68, for example, four columns of sub-pixels may be disposed between two adjacent first initial signal connection electrodes 68. In an exemplary implementation, the first initial signal connection line is electrically connected to a plurality of first initial signal lines 45 arranged in the second direction through the first initial signal connection electrode 68, to connect the plurality of first initial signal lines 45 arranged in the second direction Y into an integrated structure, to reduce the voltage drop of the first initial signal lines 45, so that the plurality of first initial signal lines 45 have a same potential, which is beneficial to improving the uniformity of the panel, avoiding display defect of the display substrate, and ensuring the display effect of the display substrate.

In an exemplary implementation, the second initial signal connection electrode 69 is disposed to be integrally formed with the second initial signal line 67. In an exemplary implementation, the second initial signal connection electrode 69 is disposed between sub-pixels of adjacent columns. In an exemplary implementation, one or more columns of sub-pixels may be disposed between two adjacent second initial signal connection electrodes 69, for example, four columns of sub-pixels are disposed between two adjacent second initial signal connection electrodes 69. In an exemplary implementation, the second initial signal connection electrode 69 is disposed to be connected to a second initial signal connection line formed subsequently through a via hole. In an exemplary implementation, the second initial signal connection line is electrically connected to a plurality of second initial signal lines 67 arranged in the second direction through the second initial signal connection electrode 69, to connect the plurality of second initial signal lines 67 arranged in the second direction Y into an integrated structure, which may reduce the voltage drop of the second initial signal lines 67, so that the plurality of second initial signal lines 67 have a same potential, which is beneficial to improving the uniformity of the panel, avoiding display defect of the display substrate, and ensuring the display effect of the display substrate.

In an exemplary implementation, one or more columns of sub-pixels may be disposed between adjacent first initial signal lines 68 and second initial signal connection electrodes 69, for example, two columns of sub-pixels may be disposed between adjacent first initial signal lines 68 and second initial signal connection electrodes 69. In an exemplary implementation, a plurality of pixel column spaces are included between a plurality of pixel columns, and the first initial signal connection electrodes 68 and the second initial signal connection electrodes 69 are located in different pixel column spaces.

(210) Patterns of a seventh insulation layer and a first planarization layer are formed. In an exemplary embodiment, forming the patterns of the seventh insulation layer and the first planarization layer may include: on the substrate on which the aforementioned patterns are formed, depositing a seventh insulation thin film first, then coating a first planarization thin film, and patterning the first planarization thin film and the seventh insulation thin film by a patterning process to form a seventh insulation layer covering the pattern of the fourth conductive layer and the first planarization layer disposed on the seventh insulation layer, the seventh insulation layer and the first planarization layer being provided with a plurality of via holes, as shown in FIG. 17, which is a diagram of a planar structure of eight sub-pixels.

In an exemplary implementation, a plurality of via holes in each sub-pixel at least include: a twelfth via hole V12, a thirteenth via hole V13, a fourteenth via hole V14, a fifteenth via hole V15 and a sixteenth via hole V16.

In an exemplary implementation, an orthographic projection of the twelfth via hole V12 on the substrate is located within a range of an orthographic projection of a fourth connection electrode 64 on the substrate, and the first planarization layer and the seventh insulation layer in the twelfth via hole V12 are etched away, exposing a surface of the fourth connection electrode 64. The twelfth via hole V12 is configured so that a data signal line formed subsequently is connected to the first connection electrode 64 through this via hole.

In an exemplary implementation, an orthographic projection of the thirteenth via hole V13 on the substrate is within a range of an orthographic projection of a sixth connection electrode 66 on the substrate, and the first planarization layer and the seventh insulation layer in the thirteenth via hole V13 are etched away, exposing a surface of the sixth connection electrode 66. The thirteenth via hole V13 is configured so that an anode connection electrode of a light emitting element formed subsequently is connected to the sixth connection electrode 66 through this via hole.

In an exemplary implementation, an orthographic projection of the fourteenth via hole V14 on the substrate is located within a range of an orthographic projection of a fifth connection electrode 65 on the substrate, and the first planarization layer and the seventh insulation layer in the fourteenth via hole V14 are etched away, exposing a surface of the fifth connection electrode 65. The fourteenth via hole V14 is configured so that a first power supply line formed subsequently is connected to the fifth connection electrode 65 through this via hole.

In an exemplary implementation, an orthographic projection of the fifteenth via hole V15 on the substrate is located within a range of an orthographic projection of the first initial signal connection electrode 68 on the substrate, and the first planarization layer and the seventh insulation layer in the fifteenth via hole V15 are etched away, exposing a surface of the first initial signal connection electrode 68. The fifteenth via hole V15 is configured so that a first initial signal connection line formed subsequently is connected to the first initial signal connection electrode 68 through this via hole.

In an exemplary implementation, an orthographic projection of the sixteenth via hole V16 on the substrate is located within a range of an orthographic projection of a second initial signal connection electrode 69 on the substrate, and the first planarization layer and the seventh insulation layer in the sixteenth via hole V16 are etched away, exposing a surface of the second initial signal connection electrode 69. The sixteenth via hole V16 is configured so that a second initial signal connection line formed subsequently is connected to the second initial signal connection electrode 67 through this via hole.

(211) A pattern of a fifth conductive layer is formed. In an exemplary embodiment, forming the fifth conductive layer may include: depositing a fifth conductive thin film on the substrate on which the aforementioned patterns are formed, and patterning the fifth conductive thin film through a patterning process to form the fifth conductive layer disposed on the first planarization layer, as shown in FIG. 28a and FIG. 28b, wherein FIG. 28a is a diagram of a planar structure of eight sub-pixels, and FIG. 28b is a schematic planar view of the fifth conductive layer in FIG. 28a. In an exemplary implementation, the fifth conductive layer may be referred to as a second source drain metal (SD2) layer.

In an exemplary embodiment, the fifth conductive layer at least includes: a data signal line 71, a first power supply line 72, an anode connection electrode 73, a first initial signal connection line 74, and a second initial signal connection line 75.

In an exemplary embodiment, a main portion of the data signal line 71 extends in the second direction Y, and the data signal line 71 is connected to the fourth connection electrode 64 through the twelfth via hole V12. Because the fourth connection electrode 64 is connected to the first region 24-1 of the active layer 24 of the fourth transistor T4 through a via hole, connection between the data signal line 71 and the first electrode of the fourth transistor T4 is achieved, and a data signal is written into the fourth transistor T4.

In an exemplary embodiment, the first power supply line 72 is in a shape of a bend line whose main portion extends in the second direction Y, and the first power supply line 72 is connected to the fifth connection electrode 65 through the fourteenth via hole V14. Because the fifth connection electrode 65 is connected to the second plate 43 through a via hole, connection between the first power supply line 72 and the second plate 43 is achieved, and a power signal is written into the second plate 43. Because the fifth connection electrode 65 is connected to the first region 25-1 of the active layer 25 of the fifth transistor T5 through a via hole, connection between the first power supply line 72 and the first electrode of the fifth transistor T5 is achieved, and a power signal is written into the fifth transistor T5.

In an exemplary embodiment, the first power supply lines 72 of sub-pixels in a same column are connected to each other to form an integrated structure, which may ensure that the first power supply lines 72 of sub-pixels in a same column have a same potential, and is beneficial to improving uniformity of the panel, avoiding poor display of the display substrate, and ensuring the display effect of the display substrate. In an exemplary implementation, the first power supply line 72 of the Nth column and the first power supply line 72 of the (N+1)th column are interconnected and integrally formed, the first power supply line 72 of the (N+2)th column and the first power supply line 72 of the (N+3)th column are interconnected and integrally formed, and the first power supply lines 72 of two adjacent columns of sub-pixels are interconnected and integrally formed, which may ensure that the first power supply lines 72 of two adjacent columns of sub-pixels have a same potential, and is beneficial to improving uniformity of the panel, avoiding display defect of the display substrate, and ensuring the display effect of the display substrate.

In an exemplary embodiment, the anode connection electrode 73 is connected to the sixth connection electrode 66 through the thirteenth via hole V13. Because the sixth connection electrode 66 is connected to the second region 26-2 (it is also the second region 27-2 of the active layer 27 of the seventh transistor T7) of the active layer 26 of the sixth transistor T6 through a via hole, connections between the anode connection electrode 73 and the second electrode of the sixth transistor T6 as well as the second electrode of the seventh transistor T7 are achieved.

In an exemplary embodiment, the main portion of the first initial signal connection line 74 extends in the second direction Y, and the first initial signal connection line 74 is connected to the first initial signal connection electrode 68 through the fifteenth via hole V15. In an exemplary implementation, the first initial signal connection line 74 is disposed between two adjacent columns of sub-pixels. In an exemplary embodiment, one or more columns of sub-pixels may be disposed between two adjacent first initial signal connection lines 74, for example, four columns of sub-pixels may be disposed between two adjacent first initial signal connection lines 74. In an exemplary implementation, the first initial signal connection line 74 is electrically connected to a plurality of first initial signal lines 45 arranged in the second direction through the first initial signal connection electrode 68, to connect the plurality of first initial signal lines 45 arranged in the second direction Y into an integrated structure, to reduce the voltage drop of the first initial signal lines 45, so that the plurality of first initial signal lines 45 have a same potential, which is beneficial to improving the uniformity of the panel, avoiding display defect of the display substrate, and ensuring the display effect of the display substrate.

In an exemplary embodiment, the main portion of the second initial signal connection line 75 extends in the second direction Y, and the second initial signal connection line 75 is connected to the second initial signal connection electrode 69 through the sixteenth via hole V16. In an exemplary implementation, the second initial signal connection line 75 is disposed between two adjacent columns of sub-pixels. In an exemplary embodiment, one or more columns of sub-pixels may be disposed between two adjacent second initial signal connection lines 75, for example, four columns of sub-pixels may be disposed between two adjacent second initial signal connection lines 75. In an exemplary implementation, the second initial signal connection line 75 is electrically connected to a plurality of second initial signal lines 67 arranged in the second direction through the second initial signal connection electrode 69, to connect the plurality of second initial signal lines 67 arranged in the second direction Y into an integrated structure, to reduce the voltage drop of the second initial signal lines 67, so that the plurality of second initial signal lines 67 have a same potential, which is beneficial to improving the uniformity of the panel, avoiding display defect of the display substrate, and ensuring the display effect of the display substrate.

In an exemplary embodiment, one or more columns of sub-pixels may be disposed between adjacent first initial signal connection lines 74 and second initial signal connection lines 75, for example, two columns of sub-pixels may be disposed between adjacent first initial signal connection lines 74 and second initial signal connection lines 75.

In an exemplary implementation, a plurality of pixel column spaces are included between a plurality of pixel columns, and the first initial signal connection line 74 and the second initial signal connection line 75 are located in different pixel column spaces, which fully utilizes the space of the sub-pixel circuit to reduce the voltage drop of the first initial signal line 45 and the second initial signal line 67 without increasing the size of the sub-pixel and changing the line width and spacing of the sub-pixel circuits, and improve the uniformity of the display panel.

So far, the drive circuit layer has been prepared on the substrate. In an exemplary implementation, in a plane perpendicular to the display substrate, the drive circuit layer may include a shielding layer, a first semiconductor layer, a first conductive layer, a second conductive layer, a second semiconductor layer, a third conductive layer, a fourth conductive layer, and a fifth conductive layer that are sequentially disposed on the substrate.

In an exemplary implementation, the drive circuit layer may include a first insulation layer, a second insulation layer, a third insulation layer, a fourth insulation layer, a fifth insulation layer, a sixth insulation layer, a seventh insulation layer and a first planarization layer, the first insulation layer is disposed between the shielding layer and the first semiconductor layer, the second insulation layer is disposed between the first semiconductor layer and the first conductive layer, the third insulation layer is disposed between the first conductive layer and the second conductive layer, the fourth insulation layer is disposed between the second conductive layer and the second semiconductor layer, the fifth insulation layer is disposed between the second semiconductor layer and the third conductive layer, the sixth insulation layer is disposed between the third conductive layer and the fourth conductive layer, and the seventh insulation layer and the first planarization layer are disposed between the fourth conductive layer and the fifth conductive layer.

In an exemplary embodiment, after the preparation of the drive circuit layer is completed, a light emitting structure layer is prepared on the drive circuit layer, and the preparation process of the light emitting structure layer may include the following acts: forming a pattern of a second planarization layer, the second planarization layer being provided with at least an anode via hole; forming a pattern of an anode, the anode being connected to the anode connection electrode through the anode via hole; forming an anode pixel definition layer, the pixel definition layer being provided with a pixel opening exposing the anode; forming an organic light emitting layer using an evaporation or ink-jet printing process, and forming a cathode on the organic light emitting layer; forming an encapsulation layer, wherein the encapsulation layer may include a first encapsulation layer, a second encapsulation layer, and a third encapsulation layer that are stacked, the first encapsulation layer and the third encapsulation layer may be made of an inorganic material, the second encapsulation layer may be made of an organic material, and the second encapsulation layer is disposed between the first encapsulation layer and the third encapsulation layer, so that it may be ensured that external water vapor cannot enter the light emitting structure layer.

In an exemplary implementation, the shielding layer, the first conductive layer, the second conductive layer, the third conductive layer, the fourth conductive layer and the fifth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, the sixth insulation layer, and the seventh insulation layer may be made of any one or more of silicon oxide (SiOx), silicon nitride (SiNx), and silicon oxynitride (SiON), and may be single layers, multiple layers, or composite layers. The first insulation layer may be referred to as a Buffer layer, which is used for improving the water and oxygen resistance of the substrate. The second insulation layer, the third insulation layer, the fourth insulation layer, and the fifth insulation layer may be referred to as a gate insulation (GI) layer, the sixth insulation layer may be referred to as an interlayer dielectric (ILD) layer, and the seventh insulation layer may be referred to as a passivation (PVX) layer.

The structure and preparation process shown in the aforementioned embodiments of the present disclosure are only an exemplary explanation. In an exemplary implementation, the corresponding structure can be changed and the patterning process can be increased or reduced according to actual needs. The display substrate of an embodiment of the present disclosure may be applied to other display devices with a pixel drive circuit, such as a quantum dot display. The present disclosure is not limited herein.

The present disclosure further provides a display device, including the display substrate according to any of the aforementioned embodiments. The display device may be any product or component with a display function, such as a mobile phone, a tablet computer, a television, a display, a laptop computer, a digital photo frame, a wearable device or a navigator.

The present disclosure further provides a preparation method for a display substrate, wherein the display substrate includes a substrate, a plurality of initial signal lines and K rows and L columns of sub-pixels are provided on the substrate, K and L are each a positive integer greater than 1; the plurality of initial signal lines extend in a first direction and are arranged in a second direction, the first direction intersects the second direction; a plurality of pixel column spaces are included between the L pixel columns, and the pixel column spaces are located between two adjacent pixel columns; the preparation method including:
disposing initial signal connection lines in at least one of the pixel column spaces, and electrically connecting at least one of the initial signal connection lines to the plurality of initial signal lines through a via hole, the initial signal connection lines extending in the second direction on a plane parallel to the display substrate.

In an exemplary implementation, the plurality of pixel column spaces include a plurality of first pixel column spaces and a plurality of second pixel column spaces, orthographic projections of the first pixel column spaces and the second pixel column spaces on the substrate do not overlap; the initial signal line includes a first initial signal line and a second initial signal line, the initial signal connection line includes a first initial signal connection line and a second initial signal connection line, the first initial signal connection line is disposed in the first pixel column space, the second initial signal connection line is disposed in the second pixel column space, the first initial signal connection line is electrically connected to the first initial signal line through a via hole, and the second initial signal connection line is electrically connected to the second initial signal line through a via hole.

For the substrate and the preparation method therefor, and the display device provided by the embodiments of the present disclosure, the display substrate includes a substrate on which a plurality of initial signal lines and K rows and L columns of sub-pixels are provided, K and L being each a positive integer greater than 1; a plurality of pixel column spaces are included between L pixel columns, the pixel column space is located between two adjacent pixel columns; at least one of the pixel column spaces is provided with initial signal connection lines, at least one of the initial signal connection lines is electrically connected to the plurality of initial signal lines through a via hole; the initial signal connection lines are disposed in the pixel column spaces, and the plurality of initial signal lines are connected through the initial signal connection lines, which reduces the voltage drop of the initial signal lines without increasing the process difficulty, and improves display uniformity.

The drawings of the embodiments of the present disclosure only involve structures involved in the embodiments of the present disclosure, and other structures may refer to usual designs.

The embodiments of the present disclosure, that is, features in the embodiments, may be combined with each other to obtain new embodiments if there is no conflict.

Although the implementation modes disclosed in the embodiments of the present disclosure are described above, contents are only implementation modes for facilitating understanding the embodiments of the present disclosure, which are not intended to limit the embodiments of the present disclosure. Any person skilled in the art to which the embodiments of the present disclosure pertain may make any modifications and variations in forms and details of implementation without departing from the spirit and scope disclosed in the embodiments of the present disclosure. Nevertheless, the scope of patent protection of the embodiments of the present disclosure shall still be subject to the scope defined by the appended claims.

1. A display substrate, comprising a substrate, wherein: a plurality of initial signal lines and K rows and L columns of sub-pixels are provided on the substrate, K and L are each a positive integer greater than 1; a plurality of pixel column spaces are arranged between L pixel columns, at least one pixel column space of the plurality of pixel column spaces is located between two adjacent pixel columns; at least one of the pixel column spaces is provided with initial signal connection lines, at least one of the initial signal connection lines is electrically connected to the plurality of initial signal lines through a via hole, on a plane parallel to the display substrate, the plurality of initial signal lines are extended in a first direction and are arranged in a second direction, the initial signal connection lines are extended in the second direction, and the first direction is intersected with the second direction.

2. The display substrate according to claim 1, wherein the plurality of pixel column spaces comprise a plurality of first pixel column spaces and a plurality of second pixel column spaces, orthographic projections of the first pixel column spaces and the second pixel column spaces on the substrate are not overlapped;
the initial signal lines comprise a first initial signal line and a second initial signal line, the initial signal connection lines comprise a first initial signal connection line and a second initial signal connection line, the first initial signal connection line is disposed in a first pixel column space, the second initial signal connection line is disposed in a second pixel column space, the first initial signal connection line is electrically connected to the first initial signal line through a via hole, and the second initial signal connection line is electrically connected to the second initial signal line through a via hole.

3. The display substrate according to claim 1, wherein:
L data signal lines corresponding to the L pixel columns respectively are provided on the substrate, on a plane parallel to the display substrate, the L data signal lines are extended in the second direction and are arranged in the first direction, in the first direction, any one of the data signal lines is located at a side of a corresponding pixel column; and
on a plane parallel to the display substrate, in the first direction, at least one pixel column space is located at a side of a data signal line away from the corresponding pixel column, the pixel column space is located between two adjacent data signal lines; or the pixel column space is located at a side of the pixel column away from a corresponding data signal line, and the pixel column space is located between two adjacent pixel columns.

4. The display substrate according to claim 2, wherein in a plane perpendicular to the display substrate, the display substrate comprises the substrate, and a first semiconductor layer, a first conductive layer, a second conductive layer, a second semiconductor layer, a third conductive layer, a fourth conductive layer and a fifth conductive layer which are sequentially stacked on the substrate;
the first semiconductor layer at least comprises active layers of a plurality of low temperature polysilicon transistors; the first conductive layer at least comprises control electrodes of the plurality of low temperature polysilicon transistors, and a first plate of a storage capacitor; the second conductive layer at least comprises a second plate of the storage capacitor and the first initial signal lines; the second semiconductor layer at least comprises active layers of a plurality of oxide transistors; the third conductive layer at least comprises control electrodes of the plurality of oxide transistors; the fourth conductive layer at least comprises first electrodes and second electrodes of the plurality of low temperature polysilicon transistors, first electrodes and second electrodes of the plurality of oxide transistors, and the second initial signal line; and the fifth conductive layer at least comprises the first initial signal connection line and the second initial signal connection line.

5. The display substrate according to claim 4, wherein:
the fourth conductive layer further comprises a first initial signal connection electrode and a second initial signal connection electrode, the second initial signal connection electrode and the second initial signal line are integrally formed; and
the first initial signal connection electrode is electrically connected to the first initial signal line and the first initial signal connection line respectively through different via holes, and the second initial signal connection line is electrically connected to the second initial signal connection electrode through a via hole.

6. The display substrate according to claim 5, wherein the plurality of low temperature polysilicon transistors comprise a first transistor as a first initialization transistor, and a first electrode of the first transistor and the first initial signal connection electrode are integrally formed.

7. The display substrate according to claim 6, wherein:
L data signal lines corresponding to the L pixel columns respectively are further provided on the substrate, on a plane parallel to the display substrate, the L data signal lines are extended in the second direction and are arranged in the first direction, in the first direction, any one of the data signal lines is located at a side of a corresponding pixel column; and
on a plane parallel to the display substrate, in the first direction, at least one pixel column space is located at a side of a data signal line of the L data signal lines away from a corresponding pixel column, the pixel column space is located between two adjacent data signal lines, the first pixel column space and the second pixel column space are alternately arranged in the first direction, two columns of sub-pixels are provided between two adjacent pixel column spaces, first electrodes of two first transistors located between two adjacent pixel column spaces are integrally formed, the first initial signal connection electrode is extended in the first direction, one end of the first initial signal connection electrode is provided with an electrode connection block, the other end of the first initial signal connection electrode is connected to the integrally formed first electrodes of the two first transistors, and there is an overlapping area between an orthographic projection of the electrode connection block on the substrate and an orthographic projection of the first pixel column space on the substrate.

8. The display substrate according to claim 7, wherein: a first power supply line is provided on the fifth conductive layer, the first power supply line is electrically connected to the second plate through a via hole, first power supply lines in a same pixel column are formed integrally, and first power supply lines corresponding to two columns of pixels located between two adjacent pixel column spaces are integrally formed.

9. The display substrate according to claim 6, wherein L data signal lines corresponding to the L pixel columns respectively are provided on the substrate, on a plane parallel to the display substrate, the L data signal lines are extended in the second direction and are arranged in the first direction, in the first direction, any one of the data signal lines is located at a side of a corresponding pixel column; and
on a plane parallel to the display substrate, in the first direction, at least one pixel column space is located at a side of the pixel column away from the corresponding data signal line, the pixel column space is located between two adjacent pixel columns, the first pixel column space and the second pixel column space are alternately arranged in the first direction, two columns of sub-pixels are provided between two adjacent pixel column spaces, the first initial signal connection electrode and first electrodes of two first transistors located on both sides of the first pixel column space are integrally formed, and there is an overlapping area between an orthographic projection of the first initial signal connection electrode on the substrate and an orthographic projection of the first pixel column space on the substrate.

10. The display substrate according to claim 9, wherein a first power supply line is provided on the fifth conductive layer, the first power supply line is electrically connected to the second plate through a via hole, and first power supply lines in a same pixel column are integrally formed.

11. The display substrate according to claim 7, wherein: the first electrode of the first transistor is electrically connected to the active layer of the first transistor and the first initial signal line through different via holes, respectively, and the first initial signal connection electrode is electrically connected to the first initial signal connection line through a via hole.

12. The display substrate according to claim 2, wherein: at least one sub-pixel comprises a pixel drive circuit electrically connected to an initial signal line of the plurality of initial signal lines, the pixel drive circuit at least comprises a plurality of transistors, and the plurality of transistors at least comprise a first transistor as a first initialization transistor and a seventh transistor as a second initialization transistor; and
a first electrode of the first transistor is electrically connected to the first initial signal line, and a first electrode of the seventh transistor is electrically connected to the second initial signal line.

13. The display substrate according to claim 12, wherein: the pixel drive circuit comprises a storage capacitor electrically connected to a second electrode of the first transistor, on a plane parallel to the display substrate, in the second direction, the first transistor and the seventh transistor are located at both sides of the storage capacitor, and the first initial signal line and the second initial signal line are located at both sides of the storage capacitor.

14. The display substrate according to claim 13, wherein: the plurality of transistors comprise a fourth transistor as a data writing transistor, a plurality of scan signal lines extending in the first direction are provided on the substrate, the plurality of scan signal lines at least comprise a first scan signal line and a third scan signal line, the first scan signal line serves as a control electrode of the seventh transistor, and the third scan signal line serves as a control electrode of the fourth transistor; and
on a plane parallel to the substrate, in the second direction, orthographic projections of the first scan signal line and the third scan signal line on the substrate are located at both sides of an orthographic projection of the storage capacitor on the substrate.

15. The display substrate according to claim 14, wherein: the plurality of transistors comprise a second transistor as a compensation transistor, a fifth transistor and a sixth transistor as light emitting transistors, the plurality of scan signal lines comprise a second scan signal line, a fourth scan signal line and a light emitting control line, the second scan signal line serves as a control electrode of the first transistor, the fourth scan signal line serves as a control electrode of the second transistor, and the light emitting control line serves as a control electrode of the fifth transistor and the sixth transistor; and
in a same pixel row, in a plane where the display substrate is located, the second initial signal line, the first scan signal line, the light emitting control line, the storage capacitor, the fourth scan signal line, the third scan signal line, the second scan signal line and the first initial signal line are sequentially arranged in the second direction.

16. The display substrate according to claim 15, wherein: the plurality of transistors comprise a third transistor as a drive transistor, and there is an overlapping area between an orthographic projection of the third transistor on the substrate and an orthographic projection of the storage capacitor on the substrate.

17. The display substrate according to claim 16, wherein the first transistor and the second transistor are oxide transistors and the third transistor to the seventh transistor are low temperature polysilicon transistors.

18. A display device, comprising a display substrate according to claim 1.

19. A preparation method for a display substrate, wherein: the display substrate comprises a substrate, a plurality of initial signal lines and K rows and L columns of sub-pixels are provided on the substrate, K and L are each a positive integer greater than 1; the plurality of initial signal lines are extended in a first direction and are arranged in a second direction, the first direction is intersected with the second direction; a plurality of pixel column spaces are arranged between the L pixel columns, and a at least one pixel column space of the plurality of pixel column spaces is located between two adjacent pixel columns, the preparation method comprising:
disposing initial signal connection lines in at least one of the pixel column spaces, and electrically connecting at least one of the initial signal connection lines to the plurality of initial signal lines through a via hole, the initial signal connection lines extending in the second direction on a plane parallel to the display substrate.

20. The preparation method for the display substrate according to claim 19, wherein: the plurality of pixel column spaces comprise a plurality of first pixel column spaces and a plurality of second pixel column spaces, orthographic projections of the first pixel column spaces and the second pixel column spaces on the substrate are not overlapped; and
the initial signal lines comprise a first initial signal line and a second initial signal line, the initial signal connection lines comprise a first initial signal connection line and a second initial signal connection line, the first initial signal connection line is disposed in a first pixel column space, the second initial signal connection line is disposed in a second pixel column space, the first initial signal connection line is electrically connected to the first initial signal line through a via hole, and the second initial signal connection line is electrically connected to the second initial signal line through a via hole.
